(19) United States
(12) Patent Application Publication
(10) Pub. No.: US 2024/0290830 A1
(43) Pub. Date: Aug. 29, 2024

(54) SILICON CARBIDE SEMICONDUCTOR DEVICE AND ELECTRIC POWER CONVERTER

(71) Applicant: Mitsubishi Electric Corporation, Tokyo (JP)

(72) Inventors: Yuichi NAGAHISA, Tokyo (JP); Takaaki TOMINAGA, Tokyo (JP); Yutaka FUKUI, Tokyo (JP)

(73) Assignee: Mitsubishi Electric Corporation, Tokyo (JP)

(21) Appl. No.: 18/576,761

(22) PCT Filed: Jul. 15, 2021
(86) PCT No.: PCT/JP2021/026592

§ 371 Date: Jan. 5, 2024

(51) Int. Cl. H01L 29/06; H01L 29/16; H01L 29/78

(52) U.S. Cl. CPC H01L 29/0619; H01L 29/0634; H01L 29/1608; H01L 29/7813

(57) ABSTRACT

An object of the present disclosure is to achieve low-resistance contact with pillar regions, reduce variations in withstand voltage, and reduce channel resistance and JFET resistance in a silicon carbide semiconductor device having an SJ structure and an insulated gate structure. An SJ-SiC-MOSFET includes an SJ region and an MOSFET region provided on the upper surface of the SJ region. The SJ region includes n-type first pillar regions and p-type second pillar regions that extend in a first direction parallel to a first main surface and that are alternately aligned in a second direction parallel to the first main surface and perpendicular to the first direction. The MOSFET region includes BPW regions extending in the second direction, connected to the second pillar regions, and aligned in the first direction at a second repetition interval that is shorter than a repetition interval of the second pillar regions.

### TECHNICAL FIELD

The present disclosure relates to a silicon carbide semiconductor device.

### BACKGROUND ART

Predominant semiconductor devices used in power electronics are vertical type devices, each having electrodes on both surfaces of a semiconductor substrate, and typical examples thereof include metal oxide semiconductor field effect transistors (MOSFETs) and insulated gate bipolar transistors (IGBTs). When an ordinary vertical MOSFET is turned into an OFF state, a depletion layer extends in a drift layer and functions as a pressure-resistant layer. If the drift layer has a small thickness or has a high impurity concentration, only a thin depletion layer is formed and this results in a reduction in the withstand voltage of the device.

On the other hand, when the MOSFET is in the ON state, current flows through the semiconductor substrate and the drift layer, and the resistance acting on this current is referred to as an ON-state resistance. The resistance of the drift layer, i.e., drift resistance, is one of main resistance components of the MOSFET because it is higher than the resistance of the semiconductor substrate. Thus, the ON-state resistance can be reduced substantially by lowering the drift resistance. A typical method of lowering the ON-state resistance is to reduce the thickness of the drift layer or to increase the impurity concentration in the drift layer. For this reason described above, there is a tradeoff between high withstand voltage and low ON-state resistance.

A super-junction structure (hereinafter, also referred to as an SJ structure) has been proposed as a structure for resolving the tradeoff between withstand voltage and ON-state resistance. In the SJ structure, a drift layer includes p-type pillars and n-type pillars that are alternately aligned in a direction orthogonal to the direction of current flow. The SJ structure includes not only depletions layer that expand from pn junction faces or metal junction faces existing in the vicinity of surfaces of semiconductor elements, but also a depletion layer that expands from a pn junction face between p-type pillars and n-type pillars. That is, the drift layer includes the depletion layer formed at the same depth as the p-type or n-type pillars. For example, in the case where the drift layer has n-type conductivity, even if the impurity concentration in the n-type pillars is increased in order to reduce the drift resistance, high withstand voltage can be maintained by maintaining the balance of impurity concentration between the n-type pillars and the p-type pillars so as to completely deplete the insides of the n-type pillars and the p-type pillars. Accordingly, the SJ structure is expected to dramatically improve the tradeoff between withstand voltage and ON-state resistance in the semiconductor device.

Examples of the method for forming the aforementioned pillars include a multi-epitaxial growth method (hereinafter, also referred to as a multi-epitaxial method) and an embedded epitaxial growth method (hereinafter, also referred to as an embedded epitaxial method). The multi-epitaxial method is a method of alternately repeating an epitaxial growth process and an ion implantation process. The embedded epitaxial method is a method of forming trenches in an epitaxial layer and further forming another epitaxial layer with which the trenches are embedded. Either of the methods has limitations on the ability to reduce the interval between pillar structures. In particular, in the case of semiconductor devices using, as a wide band gap material, silicon carbide (SiC) that is rapidly proliferating at the present time, it is difficult to reduce the interval between pillar structures due to the following reasons.

Problems with the multi-epitaxial method will be described. In SiC, the thermal diffusion coefficients of impurities are generally very low. P-type impurities such as Al and B have very low thermal diffusion coefficients in SiC. Thus, in order to form a p-type region by the multi-epitaxial method, it is necessary to form a uniform profile by implanting high-energy ions multiple times. Accordingly, the multi-epitaxial method requires to form a thick resist film for ion implantation and to form two types of regions separately, i.e., regions into which ions are to be implanted and regions into which no ions are to be implanted.

In order to form p-type pillar regions at low cost by the multi-epitaxial method, it is necessary to reduce the number of times epitaxial growth is conducted. This, however, requires a thick resist film because reducing the number of times epitaxial growths is conducted also increases ion implantation energy.

As described above, the multi-epitaxial method provides a tradeoff between process cost and the width of p-type pillar regions, and there are limits to the width of p-type pillars for realistic industrial applications.

Similar problems exist with the embedded epitaxial method. Since bonding strength between atoms in SiC is stronger than in silicon (Sc) that is in the mainstream of power devices, SiC is hard to etch by, for example, reactive ion etching (RIE). Thus, SiC has a lower selection ratio of an etching mask than Si and thus has more limits on the aspect ratio of trenches that can be formed by etching. Accordingly, even if the embedded epitaxial method is used with SiC, there are limits to the width of p-type pillars for practical use. As described above, SiC tends to have a wider pillar interval in the SJ structure than Si.

In addition to the problem on the pillar interval, SiC also has a problem of extremely high channel resistance in the MOSFET. The channel mobility in an n-type Si-MOSFET is approximately several hundreds of cm²/Vs, whereas the channel mobility in an n-type SiC-MOSFET is only as few as approximately several tens of cm²/Vs.

SiC also has a problem of extremely low hole mobility. For example, in the case of Si, the hole mobility is approximately 500 cm²/Vs and about one third of the electron mobility that is approximately 1500 cm²/Vs. In the case of SiC, on the other hand, the hole mobility is approximately 100 cm²/Vs and about one tenth of the electron mobility that is approximately 1100 cm²/Vs.

This low hole mobility adversely affects dynamic characteristics of the MOSFET. Since the dielectric breakdown field of SiC is about ten times of that of Si, electric charges accumulated in the depletion layer in the drift layer also become about 10 times. It is important for the dynamic characteristics to achieve the fast response of the depletion layer. However, in the SiC-MOSFET and particularly in p-type regions, deletion-layer charges that are 10 times of those in Si have to be charged and discharged through the holes having much lower mobility than those in Si. Thus, various malfunctions may occur unless contact regions are formed more densely in the p-type regions. Specifically, potentials occurring in the p-type regions may increase stress on the gate insulating film and may consequently cause shortening of product lifetime or a reduction in dV/dt resistance.

In the SJ-MOSFET, more depletion-layer charges are produced per unit area than in ordinary planar MOSFETs in order to acquire charge balance. Since the SJ-MOSFET has to draw these electric charges through p-type pillar regions having relatively low concentrations, the above-described problems appear more remarkably than in ordinary planar MOSFETs.

A high dielectric breakdown field, which is one of the features of SiC, has the merit of reducing the resistance of the drift layer, but on the other hand raises a problem of increasing an electric field in the gate insulating film provided in contact with SiC. The SiC-MOSFET has a problem in that the lifetime of the gate insulating film may be shortened due to an increase in the electric field in JFET regions, which has not been considered in the SiC-MOSFET having a small dielectric breakdown field. Accordingly, the SiC-MOSFET needs to include JFET regions that are narrower than those in the Si-MOSFET. Since the resistance of the JFET regions (JFET resistance) increases as the JFET regions get narrower, like the increased channel resistance, the narrow JFET regions become an obstacle to reduction in ON-state resistance, particularly in low resistance devices.

### PRIOR ART DOCUMENT

### Patent Document

Patent Document 1: Japanese Patent No. 6377302

### Non-Patent Documents

Non-Patent Document 1: T. Fujihira, Theory of Semiconductor Superjunction Devices,” Jpn. J. Appl. Phys., vol. 36, pp. 6254-6262, 1997
Non-Patent Document 2: S. K. Lee., et al., “Low resistivity ohmic titanium carbide contacts to n- and p-type 4H-silicon carbide,” Solid-State Electronics 44 (2000), 1179-1186
Non-Patent Document 3: C. Darmodya and N. Goldsmanb, “Incomplete ionization in aluminum-doped 4H-silicon carbide,” J. Appl. Phys. 126, 145701 (2019)

### SUMMARY OF THE INVENTION

### Problems to be Solved by Invention

As a method of achieving a high-performance and user-friendly SJ-MOSFET using SiC in consideration of the constraints and the problems described above, it is conceivable as disclosed in Patent Document 1 to make the repetitive interval of MOSFETs shorter than the repetitive interval of p-type pillars. This increases the channel width density of SiC and achieves a reduction in resistance.

However, the problems still remain even with such contrivances described above. Firstly, in the case where MOSFETs and p-type pillars are repeated in the same direction, the repetitive interval of the MOSFETs is limited to an integral submultiple of the repetitive interval of the p-type pillars even if the repetitive interval of the MOSFETs is made shorter than the repetitive interval of the p-type pillars. Besides, variations in withstand voltage occurs to a misalignment between the MOSFETs and an SJ region. This is because an electric field to be applied to a pn junction varies greatly depending on where the JFET regions of the MOSFETs are located between the p-type pillars.

Secondly, channel regions are not formed in upper portions of the p-type pillars whose width is limited to a relatively large value. Thus, channel resistance and JFET resistance remain higher than those in ordinary planar-type MOSFETs.

The present disclosure has been made in light of the above-described problems, and it is an object of the present disclosure to achieve low-resistance contact with pillar regions, a reduction in variations in withstand voltage, and a reduction in channel resistance and JFET resistance in a silicon carbide semiconductor device that has an SJ structure and an insulated gate structure.

### Means for Solving Problems

A silicon carbide semiconductor device according to the present disclosure includes an n-type silicon carbide substrate having a first main surface and a second main surface that are opposed to each other, an SJ region formed of silicon carbide and provided on the first main surface of the silicon carbide substrate, and an MOSFET region provided on an upper surface of the SJ region. The SJ region includes a plurality of n-type first pillar regions and a plurality of p-type second pillar regions that extend in a first direction parallel to the first main surface and that are alternately aligned in a second direction parallel to the first main surface and perpendicular to the first direction. The MOSFET region includes a plurality of BPW regions formed of p-type silicon carbide, extending in the second direction, connected to the plurality of second pillar regions, and aligned in the first direction at a second repetition interval that is shorter than a first repetition interval that is a repetition interval of the plurality of second pillar regions, a plurality of gate electrodes provided via a gate insulating film in a plurality of trenches, respectively, that are provided in the second direction above the plurality of BPW regions, respectively, a plurality of JFET regions formed of n-type silicon carbide and extending in the second direction between each adjacent two of the plurality of BPW regions and between each adjacent two of the plurality of trenches, a plurality of body regions formed of p-type silicon carbide and provided on and in contact with the plurality of JFET regions, respectively, a plurality of body contact regions formed of p-type silicon carbide, provided on the plurality of body regions, respectively, and having lower resistivity than the plurality of body regions, a plurality of impurity regions formed of n-type silicon carbide and provided on the plurality of body regions, respectively, in contact with the plurality of trenches and the plurality of body contact regions, respectively, and at least one connection region formed of p-type silicon carbide, provided in contact with at least one of the plurality of JFET regions, and connecting at least one of the plurality of BPW regions and at least one of the plurality of body regions. The silicon carbide semiconductor device further includes a top electrode provided on each of the plurality of body contact regions, and a bottom electrode provided on the second main surface of the silicon carbide substrate.

### Advantageous Effects of the Invention

The silicon carbide semiconductor device according to the present disclosure achieves low-resistance contact with the second pillar region, a reduction in variations in withstand voltage, and a reduction in channel resistance and JFET resistance. These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view of an SJ-SiC-MOSFET according to Embodiment 1 or 2.

FIG. 2 is a perspective view of a unit cell of the SJ-SiC-MOSFET according to Embodiment 1.

FIG. 3 is a perspective view of another unit cell of the SJ-SiC-MOSFET according to Embodiment 1.

FIG. 4 is a plan view of a boundary portion between an SJ region and an MOSFET region of the SJ-SiC-MOSFET 101 according to Embodiment 1.

FIG. 5 is a sectional view of the SJ-SiC-MOSFET 101 according to Embodiment 1, taken along line A1-A1′ in FIG. 4.

FIG. 6 is a sectional view of the SJ-SiC-MOSFET 101 according to Embodiment 1, taken along line A2-A2′ in FIG. 4.

FIG. 7 shows a pn diode structure used in an exemplary trial calculation of an optimum design for the SJ region.

FIG. 8 shows a relationship of the pillar pitch, the ON-state resistance, and the impurity concentration in the optimized SJ region.

FIG. 9 shows a TCAD simulation result of an electric field distribution in the upper portion of the pn diode structure in FIG. 6.

FIG. 10 shows a relationship of the impurity concentration in first pillar regions, the average current density, and the surface resistance of a path over which holes flow from intersecting regions to source electrodes.

FIG. 11 shows acceptor-impurity-concentration dependence of the hole mobility and the ionization rate in p-type regions.

FIG. 12 shows acceptor-impurity-concentration dependence of the resistivity in the p-type regions.

FIG. 13 shows a relationship between the impurity concentration in a connection region and the area proportion of the connection region in an xy plane.

FIG. 14 shows a diode structure used in TCAD calculation.

FIG. 15 shows a temporal waveform of current flowing through a cathode.

FIG. 16 shows a temporal waveform of a voltage difference between immediately upper and lower portions of a mobility degradation region.

FIG. 17 shows the result of trial calculation of the relationship between the impurity concentration in the connection region and the area proportion of the connection region in the xy plane when the connection region has resistivity of 1 mΩcm² and 0.3 mΩcm².

FIG. 18 is a perspective view of a unit cell of an SJ-SiC-MOSFET according to a first variation of Embodiment 1.

FIG. 19 is a plan view of the SJ-SiC-MOSFET according to the first variation of Embodiment 1 in an xy plane that passes through the intersecting region.

FIG. 20 is a sectional view of the SJ-SiC-MOSFET according to the first variation of Embodiment 1, taken along line A1-A1′ in FIG. 19.

FIG. 21 is a sectional view of the SJ-SiC-MOSFET according to the first variation of Embodiment 1, taken along line A2-A2′ in FIG. 19.

FIG. 22 is a perspective view of a unit cell of an SJ-SiC-MOSFET according to a second variation of Embodiment 1.

FIG. 23 is a plan view of the SJ-SiC-MOSFET according to the second variation of Embodiment 1 in an xy plane that passes through the intersecting region.

FIG. 24 is a sectional view of the SJ-SiC-MOSFET according to the second variation of Embodiment 1, taken along line A1-A1′ in FIG. 23.

FIG. 25 is a sectional view of the SJ-SiC-MOSFET according to the second variation of Embodiment 1, taken along line A2-A2′ in FIG. 23.

FIG. 26 is a perspective view of a unit cell of an SJ-SiC-MOSFET according to a third variation of Embodiment 1.

FIG. 27 is a plan view of the SJ-SiC-MOSFET according to the third variation of Embodiment 1 in an xy plane that passes through the intersecting region.

FIG. 28 is a sectional view of the SJ-SiC-MOSFET according to the third variation of Embodiment 1, taken along line A1-A1′ in FIG. 27.

FIG. 29 is a sectional view of the SJ-SiC-MOSFET according to third variation of Embodiment 1, taken along line A2-A2′ in FIG. 27.

FIG. 30 is a sectional view of an SJ-SiC-MOSFET according to a fourth variation of Embodiment 1 in an xz plane that passes through the first pillar region.

FIG. 31 is a sectional view of the SJ-SiC-MOSFET according to the fourth variation of Embodiment 1 in an xz plane that passes through a second pillar region.

FIG. 32 is a perspective view of a unit cell of an SJ-SiC-MOSFET according to Embodiment 2.

FIG. 33 is a perspective view of a unit cell of an SJ-SiC-MOSFET according to a first variation of Embodiment 2.

FIG. 34 is a perspective view of a unit cell of an SJ-SiC-MOSFET according to a second variation of Embodiment 2.

FIG. 35 is a perspective view of a unit cell of an SJ-SiC-MOSFET according to a third variation of Embodiment 2.

FIG. 36 is a block diagram of an electric power conversion system according to Embodiment 3.

### DESCRIPTION OF EMBODIMENTS

Hereinafter, embodiments will be described with reference to the accompanying drawings. Since the drawings are illustrated in schematic form, the relative relationship of the sizes and positions of images in different drawings is not always accurate and can be changed appropriately. In the following description, identical constituent elements are illustrated with the same reference numerals and assumed to have identical names and functions. Thus, detailed descriptions of these constituent elements may be omitted in some cases.

Embodiments described in the specification of the present disclosure are explained using silicon carbide (SIC) MOSFETs by way of example, in which silicon carbide (SiC) semiconductor devices are used as an example of semiconductor devices, and the n type is assumed to be a first conductivity type and the p-type is assumed to be a second conductivity type. Descriptions as to high and low of potentials are given for the case where the n type is the first conductivity type and the p type is the second conductivity type. Thus, when the p type is the first conductivity type and the n type is the second conductivity type, descriptions as to high and low of potentials are reversed. Moreover, in the entire semiconductor device, a region other than an active region in which unit cells are periodically arranged is referred to and described as an outer peripheral region according to the present application.

### A. Embodiment 1

### A-1. Configuration

First, a configuration of a silicon carbide semiconductor device according to Embodiment 1 will be described.

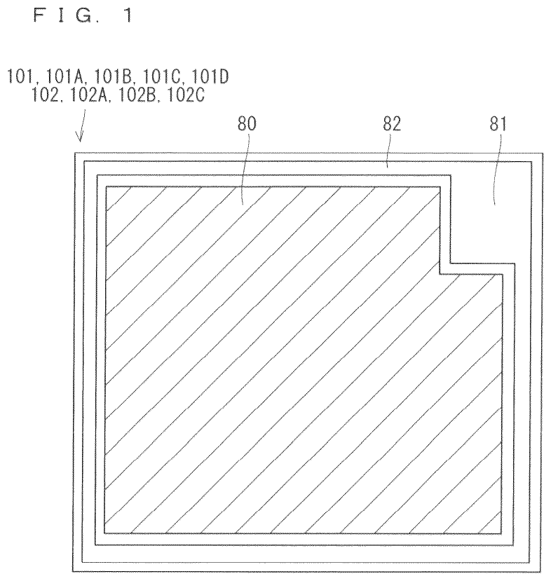

FIG. 1 is a schematic plan view of a silicon carbide MOSFET having an SJ structure (hereinafter, also referred to as an SJ-SiC-MOSFET) 101, which is a silicon carbide semiconductor device according to Embodiment 1, or an SJ-SiC-MOSFET 102, which is a silicon carbide semiconductor device according to Embodiment 2, when viewed from above. In FIG. 1 a gate pad 81 is formed on part of the upper surface of the SJ-SiC-MOSFETs 101 or 102, and a source electrode 80 is formed adjacent to the gate pad 81. Moreover, a gate line 82 is formed so as to extend from the gate pad 81.

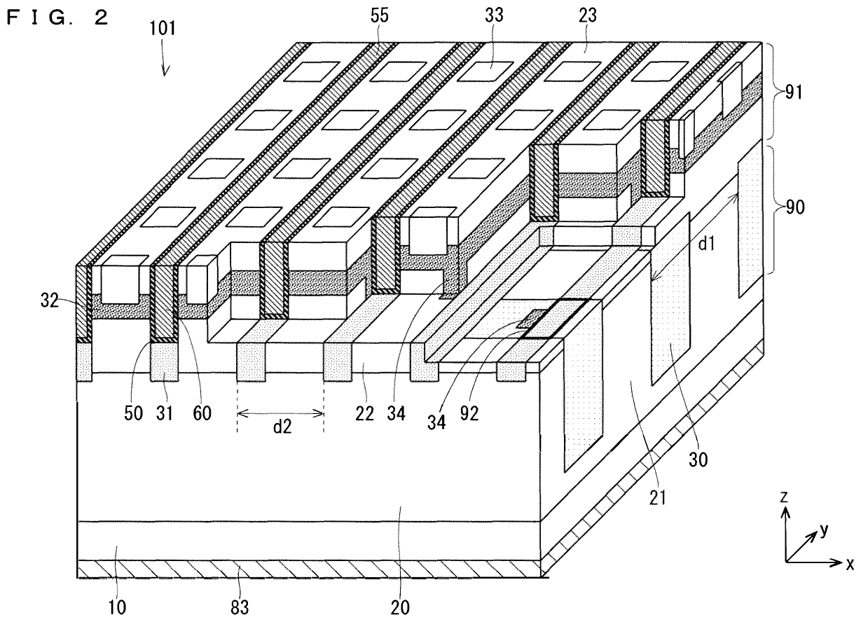

FIG. 2 is a perspective view of a unit cell of the SJ-SiC-MOSFET 101. To visualize the configuration of the unit cell, a configuration above an MOSFET region 91 is not shown in FIG. 2. The unit cell of the SJ-SiC-MOSFET 101 shown in FIG. 2 is repeated periodically under the source electrode 80 shown in FIG. 1. The z axial direction in FIG. 2 corresponds to the direction toward the surface of a chip that configures the SJ-SiC-MOSFET 101. The x and y axial directions in FIG. 2 are each a direction along one side of the chip configuring the SJ-SiC-MOSFET 101. However, these directions of the axes are not the ones uniquely defined and have certain voluntariness. The X and Y axes may be horizontal to the direction along the surface of the chip and perpendicular to the z axis and may form a certain angle or more, e.g., 10 degrees or more, with each other.

FIG. 2 is described in a concrete manner. To facilitate the description, FIG. 2 shows only a region inside a semiconductor layer formed of SiC and an area corresponding to a trench gate. To simply illustrate a three-dimensional structure, FIG. 2 shows that the SJ-SiC-MOSFET 101 is cut at various points in section.

As shown in FIG. 2, the SJ-SiC-MOSFET 101 includes an n-type silicon carbide substrate 10, an n-type drift layer 20, an SJ region 90, and the MOSFET region 91. The upper and lower surfaces of the silicon carbide substrate 10 in FIG. 2 are also referred to as first and second main surfaces, respectively.

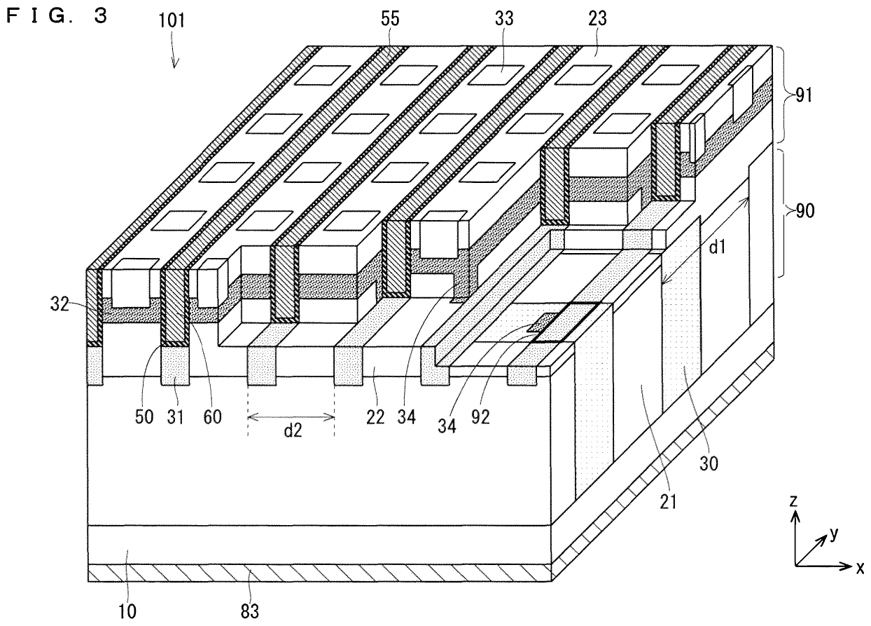

The drift layer 20 is formed on the silicon carbide substrate 10. The SJ region 90 is formed on the drift layer 20. The MOSFET region 91 is formed on the SJ region 90. Although the SJ region 90 in FIG. 2 is not in contact with the silicon carbide substrate 10, it may be in contact with the silicon carbide substrate 10 as shown in FIG. 3. That is, the SJ region 90 may be formed on the silicon carbide substrate 10 via the drift layer 20, or may be formed directly on the silicon carbide substrate 10.

The SJ region 90 includes a plurality of n-type first pillar regions 21 and a plurality of p-type second pillar regions 30. Each first pillar region 21 and each second pillar region 30 extend in the x axial direction and are alternately aligned in strips in the y axial direction at a repetition interval d1. That is, each first pillar region 21 and each second pillar region 30 extend in the x axial direction that is a first direction parallel to the first main surface of the silicon carbide substrate 10, and are alternately aligned in the y axial direction that is a second direction parallel to the first main surface and perpendicular to the x axis. The repetition interval d1 is also referred to as a first repetition interval. Only some of the second pillar regions 30 may extend to the MOSFET region 91.

Impurity concentrations in the first pillar regions 21 and the second pillar regions 30 may vary due to factors such as processing variations, but they are desirably designed so as to achieve approximate charge balance. The charge balance as used herein refers to the condition that the total sum of space charge densities when the same depth regions of the first pillar regions 21 and the second pillar regions 30 are all depleted completely becomes almost zero after cancelling out of positive and negative values. Specifically, the SJ region 90 may be designed such that the product of the width of the first pillar regions 21 and the impurity concentration in the first pillar regions 21 becomes almost equal to the product of the width of the second pillar regions 30 and the impurity concentration in the second pillar regions 30.

The MOSFET region 91 includes n-type JFET regions 22, p-type body regions 32, a source region 23 that includes n-type impurity regions, p-type body contact regions 33, a gate insulating film 50, gate electrodes 60, p-type BPW regions 31, and p-type connection regions 34.

The JFET regions 22 are formed on the SJ region 90. The body regions 32 are formed on the JFET regions 22. The source region 23 is formed on the body regions 32. The body contact regions 33 are formed so as to penetrate the source region 23 from the upper surface of the source region 23 and reach the body regions 32. From the upper surface of the source region 23, trenches 55 that penetrate the source region 23 and the body regions 32 are formed. On the inner walls of the trenches 55, the gate insulating film 50 is formed of silicon oxide having a small thickness of approximately higher than or equal to 50 nm and lower than or equal to 100 nm. Inside the trenches 55, the gate electrodes 60 are formed of polycrystalline silicon or the like via the gate insulating film 50. Here, the side surfaces of the trenches 55 may have any plane direction. For example, in the case where the polytype of a silicon carbide semiconductor is 4H—SiC and the trenches 55 are formed to have side surfaces parallel to the <11-20> direction, m-plane (1-100) or (−1100) can be used for the channel region. Accordingly, it is possible to form the channel region that has low variability and that is unsusceptible to the off-angle of the silicon carbide substrate 10.

At the bottoms of the trenches 55, the p-type BPW regions 31, each extending in the y axial direction, are formed in strips in the x axial direction at a repetition interval d2. That is, the BPW regions 31 extend in the y axial direction orthogonal to the x axial direction that is the direction of extension of the second pillar regions 30 of the SJ region 90. The repetition interval d2 of the BPW regions 31 is also referred to as a second repetition interval. The repetition interval d2 of the BPW regions 31 is shorter than the repetition interval d1 of the second pillar regions 30. The intersections of the BPW regions 31 with the second pillar regions 30 are defined as intersecting regions 92. In the intersecting regions 92, the BPW regions 31 are connected to the second pillar regions 30.

The connection regions 34 are provided in contact with or in the vicinity of the intersecting regions 92. Here, the language saying that the connection regions 34 are provided in the vicinity of the intersecting regions 92 means that the connection regions 34 are located at position where the connection regions 34 are electrically connected with low resistance to the intersecting regions 92. Specifically, the connection regions 34 may be regarded as being in the vicinity of the intersecting regions 92 if the distance between each connection region 34 and each intersecting region 92 is shorter than one fourth of a clearance distance between each pair of intersecting regions 92 that are adjacent to each other in the direction of repetition of the intersecting regions 92. The connection regions 34 extend in the longitudinal direction, which is the z axial direction, and is connected to the body regions 32. It is desirable that the impurity concentration in the BPW regions 31 may be higher than the impurity concentration in the second pillar regions 30, but it may be lower than or equal to the impurity concentration in the second pillar regions 30.

The JFET regions 22 are formed between the trenches 55 and between the BPW regions 31 so as to have a higher impurity concentration than the first pillar regions 21. The JFET regions 22 are also formed in the upper portions of the p-type second pillar regions 30.

The body regions 32 are formed on the JFET regions 22 to fill in spaces between the trenches 55. On the body regions 32, the source region 23 is formed in contact with the gate insulating film 50. The body contact regions 33 are periodically formed so as to penetrate the source region 23 and come in contact with the body regions 32.

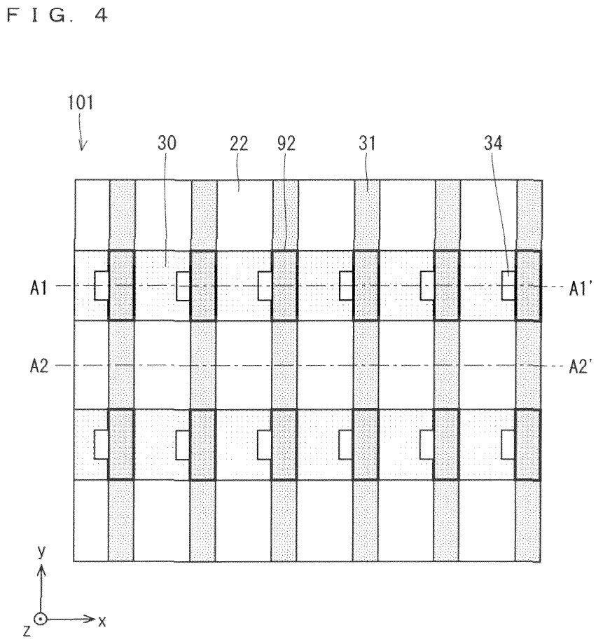

FIG. 4 is an xy-plan view of a boundary portion between the SJ region 90 and the MOSFET region 91 in the SJ-SiC-MOSFET 101. In FIG. 4, the direction perpendicular to the plane of the drawing and toward the front is defined as the positive z axial direction. As shown in FIG. 4, the intersecting regions 92 are defined at the intersections of the BPW regions31 and the second pillar regions 30. The BPW regions 31 that are formed mainly by ion implantation extends off the SJ region 90, but they may be formed by any method other than ion implantation so as not to extend off the SJ region 90. The BPW regions 31 are connected to the second pillar regions 30 at the intersecting regions 92. The connection regions 34 are formed adjacent to the intersecting regions 92 and extend in the z axial direction.

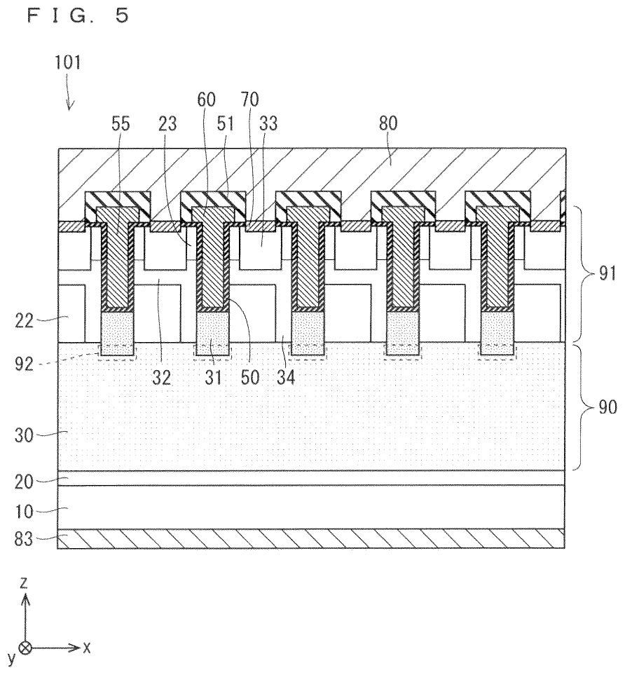

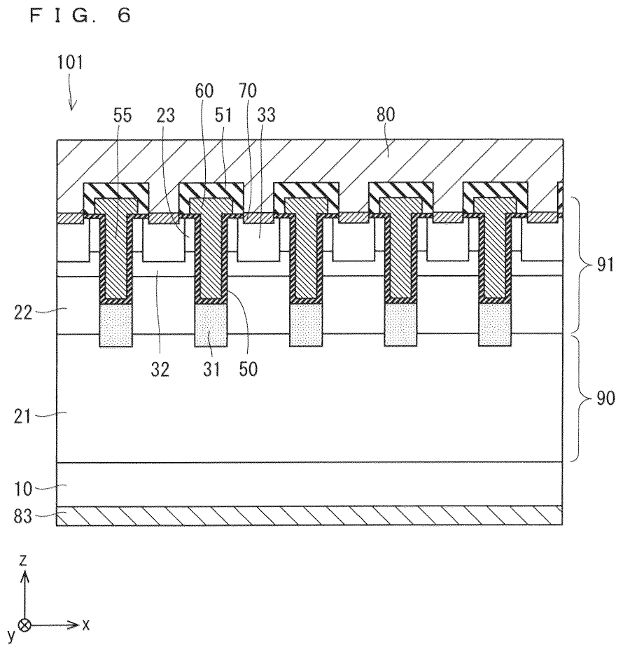

In FIG. 4, a section that is horizontal to the z axis and that passes through the center of one second pillar region 30 is defined as an A1-A1′ section. Similarly, a section that is horizontal to the z axis and that passes through the center of one first pillar region 21 is defined as an A2-A2′ section. FIG. 5 is an illustration of the A-A1′ section of the SJ-SiC-MOSFET 101, and FIG. 6 is an illustration of the A2-A2′ section of the SJ-SiC-MOSFET 101. Unlike FIGS. 2 and 3, FIGS. 5 and 6 show the structure above the MOSFET region 91 without omission.

As shown in FIGS. 5 and 6, the SJ-SiC-MOSFET 101 includes an interlayer insulation film 51, a source electrode 80 that is a top electrode, a first ohmic contact region 70, and a drain electrode 83 that is a bottom electrode. The interlayer insulation film 51 covers the top portions of the gate electrodes 60 and insulates the gate electrodes 60 from the source electrode 80. The interlayer insulation film 51 has contact holes that expose the body contact regions 33. The source electrode 80 is formed on the interlayer insulation film 51 and in the contact holes and comes in contact with the body contact regions 33 via the contact holes. Specifically, the first ohmic contact region 70 is formed at the boundaries between the source electrode 80 and the body contact regions 33, and the source electrode 80 comes in contact with the body contact regions 33 via the first ohmic contact region 70.

As shown in FIG. 5, the BPW regions 31 are connected to the second pillar regions 30 in the intersecting regions 92. The BPW regions 31 are also connected to the body regions 32 via the connection regions 34. The body regions 32 are connected to the source electrode 80 via the body contact regions 33 and the first ohmic contact region 70. This configuration reduces the resistance of the path over which holes flow from the source electrode 80 to the second pillar regions 30. The n-type JFET regions 22 are also formed on the second pillar regions 30. The JFET regions 22 contribute to continuity because they extend in the y axial direction and reach the tops of the first pillar regions 21. In FIGS. 5 and 6, the source region 23 is not in contact with the first ohmic contact region 70. However, in actuality, the source region 23 is in contact with the first ohmic contact region 70 in section between the A1-A1′ section and the A2-A2′ section and have ohmic contact with the source electrode 80.

As shown in FIG. 6, the first pillar regions 21 occupies the entire SJ region 90 in the A-A′ section. In the A2-A2′ section, the connection regions 34 do not exist in the MOSFET region 91. The other structure along the A2-A2′ section is almost similar to the structure along the A1-A1′ section shown in FIG. 5.

### A-2. Manufacturing Method

A method of manufacturing the SJ-SiC-MOSFET 101 will be described. First, a method of forming the SJ region 90 will be described. As described above, the method of forming SJ includes the multi-epitaxial method and the embedded epitaxial method, and either of them may be used to form SJ.

First, the embedded epitaxial method is described. The drift layer 20 with a thickness of greater than or equal to 5 μm and less than or equal to 200 μm is epitaxially grown on the n-type silicon carbide substrate 10 by chemical vapor deposition (CVD). The silicon carbide substrate 10 has a 4H polytype, an n-type impurity concentration of approximately 1×10¹⁸ cm⁻³ to 5×10¹⁹ cm⁻³, and a first main surface that is a plane extending in the position z axial direction and having a plane direction along the (0001) plane having an off angle. The drift layer 20 is silicon carbide having an n-type impurity concentration of 1×10¹⁴ cm⁻³ to 5×10¹⁷ cm⁻³.

Next, an SiO₂ layer is formed on the drift layer 20. Then, the SiO₂ layer is processed into strips by techniques such as photolithography and reactive ion etching (RIE). Thereafter, an etching gas that obtains the proper selection ratio to SiO₂ is used to form the trenches 55, each having a width of approximately 1 μm to 10 μm in the drift layer 20. It is desirable that the trenches 55 have a greater ratio of depth to width and they are etched deep across the drift layer 20 in the depth direction. Alternatively, the depth of the trenches 55 may approximately be half of the depth of the drift layer 20, with emphasis on reducing the width of the trenches 55. The SJ structure including such trenches 55 is also referred to as a half SJ structure or a small-sized SJ structure. The drift layer 20 that remains between the trenches 55 without being etched in forming the trenches 55 serves as the first pillar regions 21.

Next, a p-type SiC layer is epitaxially grown on the trenches 55 by CVD so that the trenches 55 are completely embedded with the p-type SiC layer. Here, typical examples of p-type impurities contained in the epitaxial layer that embeds the trenches 55 include aluminum (Al) or boron (B). In this way, the second pillar regions 30 are formed. It is desirable that the p-type impurity concentration in the second pillar regions 30 is set so as to achieve charge balance in relation to the n-type impurity concentration in the first pillar regions 21 as described above.

When the trenches 55 are embedded with the p-type epitaxial layer, the p-type epitaxial layer is also formed undesirably on mesa regions between the trenches 55. Thus, only the p-type epitaxial layer on the mesa regions are shaved off by a technique such as chemical mechanical polishing. This completes the formation of the SJ region 90, with both of the first pillar regions 21 and the second pillar regions 30 exposed to the surface of the semiconductor layer.

Next, a case of using the multi-epitaxial method is described. On the n-type silicon carbide substrate 10, an n-type epitaxial layer having a thickness of approximately several hundreds of nm to several tens of μm is formed by CVD. Thereafter, an SiO₂ film is formed on the n-type epitaxial layer and patterned by photolithography to generate a mask for ion implantation. Then, ions are implanted while changing the dose and the implantation energy within a range that the mask for ion implantation is not penetrated, so as to form p-type regions that have a uniform impurity concentration in the depth direction. Here, the implantation energy with which the mask for ion implantation is not penetrated depends on the thickness of the mask for ion implantation, and may be in the range of, for example, several hundreds of keV to several MeV. Examples of elements to be implanted include B and Al. Thereafter, the mask for ion implantation is removed.

Thereafter, an n-type epitaxial layer is formed again, and the p-type regions are extended in the depth direction by the aforementioned method. By repeating this process multiple times, resultant p-type regions become the second pillar regions 30, and the n-type epitaxial layer between the second pillar regions 30 becomes the first pillar regions 21. This completes the formation of the SJ region 90.

Although the method of forming p-type regions by implanting ions into an n-type epitaxial layer has been described thus far for simplification, the n type and the p type may be reversed. As another alternative, after formation of an n-type epitaxial layer having a low impurity concentration is formed, and ions may be implanted into the entire surface of the n-type epitaxial layer so as to form an n-type region that makes the drift layer 20 or the first pillar regions 21. In general, ion implantation exhibits a smaller range of impurity variations than epitaxial growth and therefore allows a reduction in deviation from the charge-balanced state of the SJ region 90. Accordingly, it is possible to reduce variations in ON-state resistance or withstand voltage and to realize the high-yield SJ region 90. Alternatively, although cost may increase, a mask for n-type regions and a mask for p-type regions individually may be formed individually in order to further improve the degree of flexibility. In general, impurities to be implanted to form the n-type regions are nitrogen (N) or phosphorus (P).

The cost of the multi-epitaxial method depends mainly on the number of times multi-epitaxial growth is conducted. Meanwhile, reducing the number of time multi-epitaxial growth is conducted requires a special process such as setting the ion implantation energy to MeV and leads to deterioration in performance such as an increase in implantation defects due to increased implantation energy or an increase in processing dimensions due to increased thickness of the implantation mask. Although details will be described later, in general performance improves, i.e., the ON-state resistance at the same withstand voltage decreases, as the SJ-MOSFET scales down (shrinks), i.e., as the second pillar regions 30 have a higher aspect ratio, a higher p-type impurity concentration, and a shorter repetition interval. Accordingly, the multi-epitaxial method makes a tradeoff between cost and performance, and the balance between cost and performance is determined mainly by the number of times multi-epitaxial growth is conducted.

In both of the embedded epitaxial method and the multi-epitaxial method, the relationship of impurity concentrations in the silicon carbide substrate 10, the drift layer 20, and the SJ region 90 is as follows. Referring first to the n-type regions, the silicon carbide substrate 10 has the highest impurity concentration. The impurity concentration in the drift layer 20 is designed to be lower than the impurity concentration in the first pillar region 21. Next, the p-type impurity concentration in the second pillar regions 30 varies depending on the design of charge balance in the SJ region 90. In the specification of the present disclosure, it is basically assumed that charge balance is achieved if the ratio of the total amount of donor to the total amount of acceptors falls within the range of 0.5 to 2 in an xy plane where the depth of the SJ region 90 in the active region is constant.

Next, a method for forming the MOSFET region 91 will be described. First, an n-type epitaxial layer is formed on the SJ region 90. Here, the formed epitaxial layer may be used as-is for the JFET regions 22 by controlling epitaxial conditions so as to obtain the impurity concentration in the JFET regions 22. This reduces the number of steps for forming the JFET regions 22. Alternatively, after an n-type epitaxial layer having a lower impurity concentration of, for example, 1×10¹⁴ cm⁻³ is formed, the epitaxial layer may be subjected to ion implantation so as to increase the n-type impurity concentration and to form the JFET regions 22. This method reduces variations in the impurity concentration in the JFET regions 22 and achieves a reduction in product variations and an increase in yield.

One feature of the SiC-MOSFET 101 is that the impurity concentration in the JFET regions 22 is higher than the impurity concentrations in the drift layer 20 and the first pillar regions 21. This allows MOSFETs formed on the second pillar regions 30 to contribute to current continuity via the JFET regions 22. The impurity concentration in the JFET regions 22 may be in the range of, for example, 5×10¹⁶ cm⁻³ to 1×10¹⁸ cm⁻³. Note that the impurity concentration in the JFET regions 22 may be the same as the impurity concentration in the first pillar regions 21.

Then, the p-type body regions 32 are formed by implanting acceptor ions such as A1 into the surface layers of the JFET regions 22. The impurity concentration in the body regions 32 may be in the range of, for example, 5×10¹⁷ cm⁻³ to 1×10¹⁹ cm⁻³. The impurity concentration in the body regions 32 is higher than the impurity concentration in the JFET regions 22. The depth of the body regions 32 may be in the range of approximately 0.5 μm to 2 μm. If the body regions 32 are deep, it is possible to increase the channel length and thereby to increase tolerance to short circuits. Alternatively, a p-type epitaxial layer may be formed as the body regions 32 on the JFET regions 22.

Then, the n-type source region 23 and the p-type body contact regions 33 are formed in the surface layers of the body regions 32 by ion implantation and photolithography. The source region 23 is formed by implantation of ions such as N ions or P ions. The n-type impurity concentration in the source region 23 is higher than or equal to 1×10¹⁸ cm⁻³ and lower than or equal to 1×10²¹ cm⁻³ and exceeds the p-type impurity concentration in the body regions 32. The body contact regions 33 are formed by implantation of ions such as A1 ions or B ions. The impurity concentration in the body contact regions 33 is higher than or equal to 5×10¹⁸ cm⁻³ and lower than or equal to 1×10²² cm⁻³ and exceeds the p-type impurity concentration in the body regions 32.

Then, a mask for trench etching is formed by deposition of an SiO₂ film and photolithography. Then, using this mask, the trenches 55 that penetrate the body regions 32 are formed by RIE or any other technique. Moreover, the p-type BPW regions 31 are formed on the underside of the trenches 55 by ion implantation. At this time, the number of steps for forming masks may be reduced by using the mask for etching of the trenches 55 also as the mask for ion implantation for forming the BPW regions. It is desirable that the p-type impurity concentration in the BPW regions 31 is higher than or equal to the p-type impurity concentration in the body regions 32.

Next, the p-type connection regions 34 are formed by, for example, photolithography and graded ion implantation into the trenches 55. The connection regions 34 may be formed in contact with or in the vicinity of the intersecting regions 92. The p-type impurity concentration in the connection regions 34 may be higher than or equal to the p-type impurity concentration in the body regions 32.

Then, using heat treatment equipment, annealing is conducted for 30 seconds to one hour at a temperature higher than or equal to 1300° C. and lower than or equal to 1900° C. in an inert gas atmosphere such as an argon (AR) gas atmosphere. This annealing electrically activates the n-type impurity ions and the p-type impurity ions implanted in the silicon carbide semiconductor layer.

Then, the surface of the silicon carbide semiconductor layer is thermally oxidized so as to form a silicon oxide film having a desired thickness as the gate insulating film 50 on the inner walls of the trenches 55. Moreover, a polycrystalline silicon film with conductivity is formed by low-pressure CVD on the gate insulating film 50 and then patterned so as to form the gate electrodes 60 in the trenches 55. Thereafter, the interlayer insulation film 51 formed of silicon oxide is formed by low-pressure CVD.

Then, contact holes are formed that penetrate the interlayer insulation film 51 and the gate insulating film 50 and reach the body contact regions 33 and the source region 23 in the active region. Note that in FIGS. 5 and 6, the contact holes formed in the interlayer insulation film 51 and the gate insulating film 50 do not reach the source region 23. However, in xz planes that does not pass through the body contact regions 33, the contact holes formed in the interlayer insulation film 51 and the gate insulating film 50 reach the source region 23.

Then, a metal film composed primarily of Ni is formed by sputtering or any other technique. Moreover, heat treatment is conducted at a temperature ranging from 600° C. to 1100° C. so as to cause the metal film composed primarily of Ni to react with the silicon carbide layer of the body contact regions 33 and to form silicide between the metal film and the silicon carbide layer. Following this, the remaining metal film other than the silicide induced by the above reaction is removed by wet etching. Accordingly, the remaining silicide makes the first ohmic contact region 70.

Thereafter, a metal film composed primarily of Ni is formed on the second main surface, which is the rear surface of the silicon carbide substrate 10, and subjected to heat treatment so as to form a second ohmic region (not shown).

Note that the outer peripheral region is also formed at the same time by the processes described thus far. The outer peripheral region is assumed to have a common structure. For example, an additional process may be provided to form a field insulation film on the underside of the polycrystalline silicon film on the outer periphery.

Then, line metal such as A1 is formed on the surface side of the silicon carbide substrate 10 by sputtering or evaporation and processed into a predetermined shape by photolithography so as to form the source electrode 80, the gate pad 81, and the gate line 82. The source electrode 80 and the gate pad 81 are in contact with the first ohmic contact region 70 and the gate electrodes 60, respectively.

Finally, the drain electrode 83, which is a metal film, is formed on the surface of the second ohmic region (not shown) formed on the rear surface of the silicon carbide substrate 10. This completes the formation of the SiC-MOSFET 101 shown in FIGS. 1 to 6.

### A-3. Operations

Next, operations of the SJ-SiC-MOSFET 101 will be described. The following description is given by taking, as an example, a case in which the semiconductor material for the SJ-SiC-MOSFET 101 is 4H-type silicon carbide. While power devices operate in various ways in electric power converters such as inverters, the OFF state, the ON state, and switching operations (turn-on and turn-off) of the SJ-SiC-MOSFET 101 are described as states and operations in which the SJ-SiC-MOSFET 101 achieves its advantageous effects.

### A-3-1.OFF State

First, a general OFF state that is common to n-channel SJ-MOSFETs will be described. In the OFF state, the gate voltage is less than or equal to a threshold value and generally either 0V or minus several volts, and the MOSFETs are in a high resistance state with no n-channels formed therein. In the case of an inverter, a high voltage is applied to the drain of the device in this OFF state. When a positive voltage is applied to the drain, a reverse bias is applied to the pn junctions between the first pillar regions 21 and the second pillar regions 30 in the SJ region 90. Thus, a depletion layer gets longer in the lateral direction of the SJ region 90. When the drain voltage exceeds a certain value, the first pillar regions 21 and the second pillar regions 30 are depleted completely. This considerably increases the resistance between the drain and the source and maintains the OFF state. At this time, if charge balance is imperfect, either of the first pillar regions and the second pillar regions are depleted completely, whereas the other pillar regions are not depleted completely. Thus, an electric field occurs needlessly.

If the drain voltage increases more in the OFF state, a longitudinal electric field increases this time. While depending on design, the magnitude of the electric field becomes a maximum mainly at the lowermost portion of the SJ region 90 or at the pn junctions between the body regions 32 and the JFET regions 22. If the maximum electric field at this time exceeds a dielectric breakdown field of SiC (approximately 3 MV/cm), dielectric breakdown occurs due to the avalanche current.

From this, it is found that adjusting charge balance between the first pillar regions 21 and the second pillar regions 30 is very important in the design of SJ-MOSFETs. For example, the theory introduced by Fujihira (Non-Patent Document 1) is famous as a theory as to optimizing the design of the first pillar regions 21 and the second pillar regions 30. The technique according to the present disclosure is premised on the use of the SJ structure that is optimized based on the Fujihira's theory.

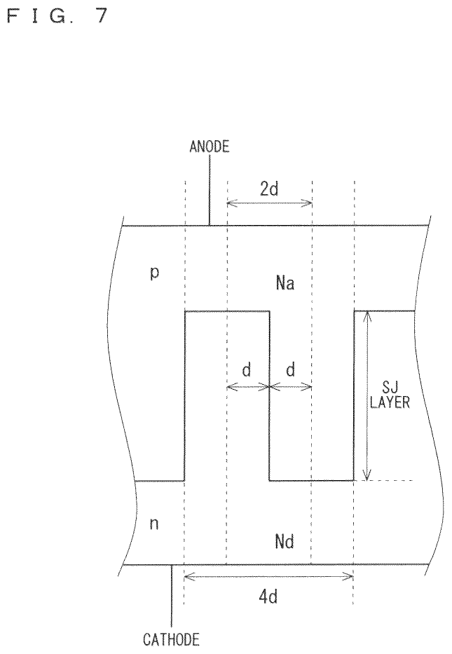

By way of example, the result of optimum design of the SJ region will be described. For simplification, a pn-diode structure is considered in which p-type pillars and n-type pillars have the same width as shown in FIG. 7. In the case where optimum design based on the Fujihira's theory is made on this pn-diode structure, the ON-state resistance of the SJ layer and the withstand voltage of the device are obtained from the following expression.

$$\begin{matrix}Math . 1 & \\ {R}_{on . sp} = \frac{4 {dV}_{B}}{{μϵ}_{S} {E}_{C}^{2}} & ( 1 )\end{matrix}$$

In Expression (1), R_{on.sp} is the ON-state resistance, d is the pillar width divided by 2, V_{B} is the withstand voltage, u is the mobility, εₛ, is the dielectric constant of the semiconductor, and E_{C} is the dielectric breakdown field.

Under optimum design conditions that satisfy Expression (1), the maximum electric field induced by the application of V_{B} to the cathode becomes exactly E_{C}, and a breakdown thereof is expressed by Expressions (2) and (3) below.

$$\begin{matrix}Math . 2 & \\ {E}_{C} = {E}_{zmax} + {E}_{xmax} & ( 2 )\end{matrix}$$

$$\begin{matrix}Math . 3 & \\ {E}_{zmax} = {E}_{xmax} & ( 3 )\end{matrix}$$

Here, E_{zmax} is the maximum longitudinal electric field in the central portion of the SJ layer, and Eₓₘₐₓ is the maximum lateral electric field in the same central portion of the SJ layer.

In the structure shown in FIG. 6, the p-type pillars have the same width and the same impurity concentration as those of the n-type pillars. When the cathode voltage rises to a certain voltage, a depletion layer expands by an amount d from the pn junction surfaces into the n-type pillars and the p-type pillars. At this time, the n-type pillars and the p-type pillars are depleted completely, and the electric field Eₓₘₐₓ is applied in the lateral direction in the central portion of the SJ layer and applied in the longitudinal direction in upper and lower ends of the pillar central portions of the SJ layer. At the dielectric breakdown, the electric field E_{zmax} is applied in the longitudinal direction in the central portion of the SJ layer, and the electric field (Eₓₘₐₓ+E_{zmax}) is applied in the longitudinal direction to the upper and lower ends of the pillar central portions of the SJ layer. Then, dielectric breakdown occurs when this value has reached the dielectric breakdown field. In the case of this structure, it is possible to maximize the withstand voltage and the ON-state resistance by making a design so that the longitudinal electric field and the lateral electric field become equal as expressed by Expression (3).

The impurity concentrations N in the n-type pillars and the p-type pillars at this time are obtained as follows by Expressions (2) and (3) and the Gauss's law.

$$\begin{matrix}Math . 4 & \\ {Q}_{x} = {ϵ}_{S} {E}_{xmax} = \frac{{ϵ}_{s} {E}_{C}}{2} = qNd & ( 4 )\end{matrix}$$

$$N = \frac{{ϵ}_{S} {E}_{C}}{2 d q}$$

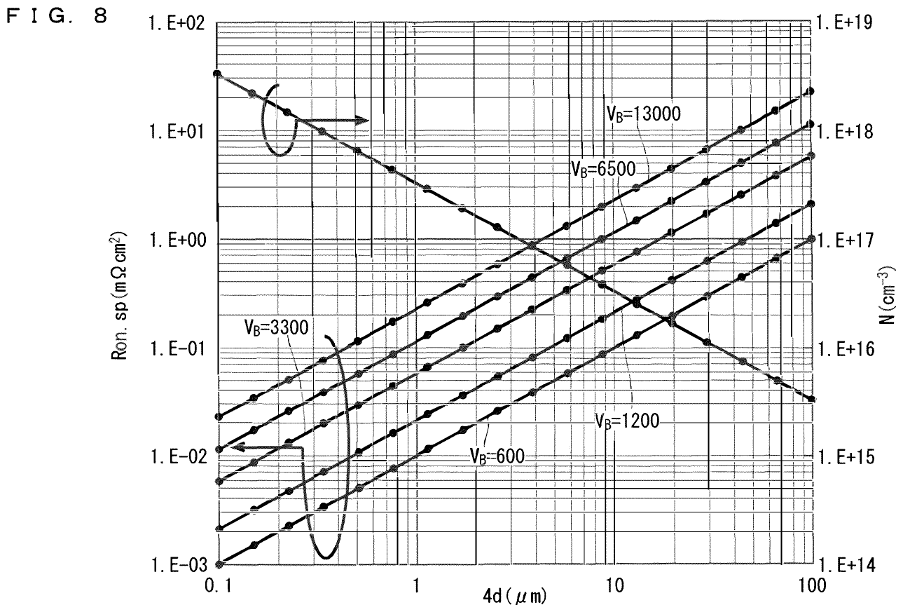

FIG. 8 shows the result of calculating the relationship of pillar pitch 4d (μm), ON-state resistance R_{on.sp} (mΩcm²), and impurity concentration N (cm⁻³) in accordance with Expressions (4) and (1), the pillar pitch being the repetition interval of the pillars. This shows the tendency that, as the pillar pitch 4d decreases, the ON-state resistance R_{on.sp} decreases and the impurity concentration N increases. Thus, it can be said that, if the ON-state resistance R_{on.sp} is reduced by reducing the pillar pitch 4d, the total electric charge necessary for charging and discharging of the pillars tends to increase at the same time.

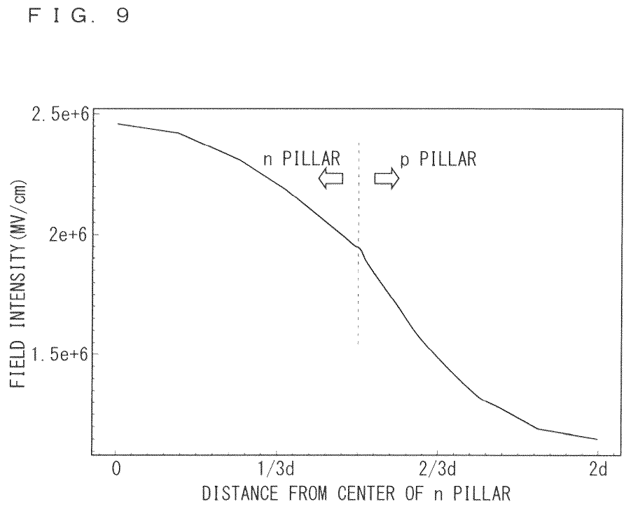

The fact that the SJ pillars are depleted completely depleted during retention of the withstand voltage has already been described. The electric field distribution in the SJ pillars at this time is as shown in FIG. 9. FIG. 9 shows the result of calculating the electric field induced by TCAD simulation conducted on a pn-diode structure of SiC that is equivalent to the structure obtained by extracting half of the repetition interval (half pitch) of the pn diode structure shown in FIG. 7. The field intensity represented by the vertical axis in FIG. 9 is obtained by extracting the value in the vicinity of the uppermost portion of the SJ layer in which dielectric breakdown is likely to occur. The horizontal axis in FIG. 9 represents the distance from the center of the n-type pillar by using d, which is the half value of the pillar width. It can be seen from FIG. 9 that the field intensity gets higher as the distance to the center of the n-type pillar decreases. Thus, for example, if a plurality of JFET regions are formed in the SJ pillar and a repeated structure parallel to the SJ pillar is assumed as shown in Patent Document 1, even a slight misalignment of patterns between the SJ pillar and the MOSFET region causes variations in the maximum electric field applied to the JFET regions of the MOSFET changes, and consequently causes variations in withstand voltage. On the other hand, in the SJ-SiC-MOSFET 101 according to the present embodiment, the maximum electric field is not affected by the magnitude of the misalignment because the JFET regions 22 of the MOSFET region 91 intersect with the first pillar regions 21 and the second pillar regions 30. Accordingly, it is possible to reduce variations in withstand voltage.

### A-3-2. ON State

In the ON state, a positive voltage greater than or equal to a threshold value, e.g., approximately 15V, is applied to the gate electrodes 60. At this time, an n-type inversion-layer channel is induced in the channel region immediately under the gate insulating film 50, i.e., at the interfaces between the gate insulating film 50 and the body regions 32 that are sandwiched between the n-type JFET regions 22 and the source region 23. Accordingly, the source region 23 and the JFET regions 22 are connected with low resistance to each other and, as a result, the drain electrode 83 and the source electrode 80 are connected with low resistance to each other.

The SJ-SiC-MOSFET 101 reduces the JFET resistance and the channel resistance because not only the strip directions of the SJ region 90 and the MOSFET region 91 intersect with each other, but also the JFET regions 22 are formed on the second pillar regions 30. As shown in FIG. 2, even the MOSFETs on the second pillar regions 30 allow passage of current to the first pillar regions 21 via the JFET regions 22.

The advantageous effects of the SJ-SiC-MOSFET 101 are quantified. The ON-state resistance of the SJ-SiC-MOSFET 101 can be expressed approximately by the following expression.

$$\begin{matrix}Math . 5 & \\ {R}_{on . sp} = {R}_{s u b} + {R}_{driftsj} + {R}_{c h} + {R}_{J F E T} & ( 5 )\end{matrix}$$

Here, R_{on.sp} is the ON-state resistance, R_{sub} is the substrate resistance, R_{driftSJ} is the resistance of the drift layer 20 and the first pillar regions 21, R_{JFET} is the resistance of the JFET regions 22, and R_{ch} is the channel resistance. Among them, R_{JFET} can be decomposed as follows.

$$\begin{matrix}Math . 6 & \\ \frac{1}{{R}_{J F E T}} = \frac{1}{{R}_{J F E T m o s}} * α + \frac{1}{{R}_{JFETmos} + {R}_{J F E Tsρred}} ( 1 - α ) & ( 6 )\end{matrix}$$

Here, R_{JFETmos} is the resistance that contributes to the ON-state resistance in a current distribution for the case when the SJ region 90 is an ordinary n-type drift layer that does not include the p-type second pillar regions 30. R_{JFETspred} is the additional resistance component generated due to the current flowing around to the tops of the second pillar regions 30. Also, a is the proportion of the first pillar regions 21 in the SJ region 90 and specifically is the value obtained by dividing the width of the first pillar regions 21 by the repetition interval d1 of the second pillar regions 30. Basically, both R_{JFETmos} and R_{JFETspred} can be reduced by increasing the impurity concentration in the JFET regions 22. If the impurity concentration in the JFET regions 22 is higher than the impurity concentration in the first pillar regions 21, the JFET resistance becomes low enough. If the proportion α of the first pillar regions 21 in the SJ region 90 is increased, the ON-state resistance can be reduced more because the contribution of R_{JFETspred} to the JFET resistance is lowered.

As a comparative example, a conventional SJ-MOSFET is considered. In the conventional SJ-MOSFET, MOSFETs are not formed on the second pillar regions 30. Thus, if the repetition interval of MOSFETs is assumed to be approximately the same as that in the SJ-SiC-MOSFET 101, the ON-state resistance can be expressed by the following expression.

$$\begin{matrix}Math . 7 & \\ {R}_{o n . s p} = {R}_{s u b} + {R}_{driftSJ} + {R}_{c h} / α + {R}_{JFETmos} / α & ( 7 )\end{matrix}$$

In Expression (7), the third term on the right-hand side represents the channel resistance, and the fourth term on the right-hand side represents the JFET resistance. The proportion α of the first pillar regions 21 in the SJ region 90 is less than or equal to 1. Thus, the channel resistance and JFET resistance of the conventional SJ-MOSFET are higher than those of the SJ-SiC-MOSFET 101.

### A-3-3.Turn-Off

Next, turn-off is described from among the switching operations. Turn-off is the operation in which the gate voltage is switched to a voltage less than or equal to a threshold value, e.g., 0V or −10V, from a state in which the ON-state current flows with low resistance so that the n-channel disappears and the MOSFET transitions to the OFF state At this time, the drain voltage increases rapidly and thereafter the current drops to a value in the vicinity of zero.

The transition of the device condition in the turn-off state is described. First, current I_{L} toward a load such as an electric motor flows through the device in an ON-voltage state in which the drain voltage is low. When electric charges are removed from gate terminals by a gate driver, the gate voltage starts to drop. Accordingly, the resistance of the channel region increases, the drain voltage starts to increase, the MOSFET transitions from the linear region to the saturated region, and a depletion layer starts to expand in the JFET regions 22 and the drift layer 20. In the early stages of the turn-off operation, the electric charges removed from the gate, i.e., the current flowing from the gate in the direction toward the driver, is mainly consumed to compensate for electric charges caused by expansion of the depletion layer. When expressed in terms of circuits, the gate current is consumed in order to accumulate negative electric charges on the gate side of gate-drain capacitance Cgd. Thus, the gate voltage remains unchanged, and only the drain voltage increases rapidly. This period is referred to as a Miller period. The drain voltage rises up to a voltage V_{L} of the load.

After the increase of the drain voltage, the gate voltage starts to drop and simultaneously the current starts to decrease. This is because, since the depletion layer has expanded enough to hold the load voltage V_{L} and the gate-drain capacitance Cgd has been charged enough with electric charges, the gate current can be used to vary the gate voltage, i.e., to charge and discharge gate-source capacitance Cgs. When the current has dropped to a value in the vicinity of zero (to a withstand voltage leakage level of the device) and furthermore the gate voltage has reached a preset OFF-state voltage, the turn-off operation is completed.

A time quadrature of the product of the drain current and the drain voltage induced during these series of turn-off period is referred to as turn-off loss out of switching loss. In order to reduce the turn-off loss, it is necessary to shorten the Miller period by increasing the rate of increase of the drain voltage while constant current I_{L} is flowing. In general, reducing Cgd is effective to shorten the Miller period.

The SJ-SiC-MOSFET 101 has a feature that the directions of extension of the first pillar regions 21 and the second pillar regions 30, which configure the SJ region 90, intersect with the direction of extension of the BPW regions 31 of the MOSFET region 91. During the Miller period that is the first half of the turn-off operation, the depletion layer starts to expand from the pn junctions of the first pillar regions 21 and the second pillar regions 30 in the SJ region 90. At this time, charging and discharging charges flow through the intersecting regions 92 to the BPW regions 31 and the connection regions 34 and flow from the body regions 32 through the body contact regions 33 to the source electrode 80. The current induced by the charging and discharging charges is spatially concentrated in the intersecting regions 92 and the connection regions 34. Here, SiC has a problem that the hole mobility is considerably lower than the electron mobility. If the connection regions 34 are not formed with low enough resistance, smooth discharge of the charging and discharging charges becomes difficult.

In the turn-off operation, if holes are not discharged smoothly to the source electrode 80, malfunctions as described below occur. Firstly, electric potentials in the connection regions 34 and the BPW regions 31 rise due to the influence of the drain voltage. Specifically, a delay in discharging holes results in excess positive charges and increases the potentials. As a result, a large electric field is applied to the gate insulating film 50 between the gate electrodes 60 and both of the BPW regions 31 and the connection regions 34, which may cause breakdown in the worst case. Even if breakdown does not occur, the application of additional stress to the gate insulating film 50 shortens the lifetime of the gate insulating film 50.

Therefore, it is necessary to form the current-carrying path from the intersecting regions 92 to the source electrode 80 in order to prevent breakdown of the gate insulating film 50 or shortening of the lifetime of the gate insulating film 50. First, the amount of charges Qₜₒₜ (C/cm²) per unit area required to completely deplete the first pillar regions 21 is obtained. Qₜₒₜ is equal to the total amount of impurities in the second pillar regions 30 in the vicinity of the intersecting regions 92 as shown in FIG. 2. Thus, Qₜₒₜ is expressed by the following expression:

$$\begin{matrix}Math . 8 & \\ {Q}_{tot} = q L β N α & ( 8 )\end{matrix}$$

where L is the depth of the SJ region 90, β is the proportion of the width of the second pillar region 30 in the SJ pillar pitch d1 (β=width of second pillar regions 30/d1), and Na is the impurity concentration.

Here, q is the elementary charge. the connection regions 34, the BPW regions 31, and the other p-type regions need to be designed such that, when the amount of charges Qₜₒₜ is discharged during a voltage rise time tᵣᵢₛₑ at turn-off, the voltage generated in the p-type regions in the vicinity of the intersecting regions 92 becomes at least 5V or less.

The voltage rise time tᵣᵢₛₑ depends on the load voltage V_{L} and the rate of voltage rise (dV/dt) at turn-off. In SiC devices used in power electronics equipment, it is desirable to consider up to approximately 100 kV/μs as dV/db because of the progress of technology that enables high-speed operations. In this case, tᵣᵢₛₑ can be expressed by the following expression.

$$\begin{matrix}Math . 9 & \\ {t}_{r i s e} = \frac{{V}_{L}}{\frac{dV}{dt} \vert turn - off} = ( 1 \times 1 {0}^{- 11} ) * {V}_{L} & ( 9 )\end{matrix}$$

From Expressions (8) and (9), the average current density iₐᵥₑ (A/cm²) when current is caused to flow by the discharge of electric charges in the SJ region 90 during the voltage rise at turn-off can be expressed as follows.

$$\begin{matrix}Math . 10 & \\ {i}_{a v e} = \frac{{Q}_{tot}}{{t}_{r i s e}} = \frac{( 1 \times 1 {0}^{11} ) q L β N α}{{V}_{L}} & ( 10 )\end{matrix}$$

Moreover, assuming that, when the voltage V_{B} is applied under optimum design that satisfies Expression (3), the depth L of the SJ region 90 is almost equal to the depth of the drift layer 20, the relationship between the electric field and the withstand voltage can be expressed by the following expression.

$$\begin{matrix}Math . 11 & \\ {V}_{B} = {E}_{xmax} * L & ( 11 )\end{matrix}$$

This expression means that the drift layer 20 is regarded as an insulation film whose space charge is zero and whose dielectric breakdown field is half of Ec of SiC (*.* Ec/2=Eₓₘₐₓ). This is due to the fact that the influence of the potential distribution exerted by the space charge is ignorable in a macroscopic level because of charge balance. From Expressions (2), (3), (4), and (11), Na can be expressed by the withstand voltage and the following expression is obtained.

$$\begin{matrix}Math . 12 & \\ {V}_{B} = \frac{{E}_{C} L}{2} = \frac{2 {qd}_{1} β N α}{2 {ϵ}_{S}} * \frac{L}{2} = \frac{q {d}_{1} β N α L}{2 {ϵ}_{S}} & ( 12 )\end{matrix}$$

Here, N═Na and d=d1×β/2. Expression (12) is modified into the following expression.

$$\begin{matrix}Math . 13 & \\ N α L = {βϵ}_{S} {V}_{B} / {qd}_{1} & ( 13 )\end{matrix}$$

Here, the load voltage V_{L} is generally designed to be lower enough than the avalanche voltage. Thus, for example, if V_{L}=V_{B}/2, the following expression is obtained.

$$\begin{matrix}Math . 14 & \\ N α L = \frac{4 {ϵ}_{S} {V}_{L}}{q β {d}_{1}} & ( 14 )\end{matrix}$$

When NaL is deleted in accordance with Expressions (9) and (14), the average current density iₐᵥₑ can be expressed by the following expression.

$$\begin{matrix}Math . 15 & \\ {i}_{ave} = \frac{( 1 \times 1 {0}^{11} ) q}{q β {d}_{1} {V}_{L}} * 4 {βϵ}_{S} {V}_{L} = \frac{( 4 \times 1 {0}^{11} ) {ϵ}_{S}}{{d}_{1}} & ( 15 )\end{matrix}$$

In this way, the average current density at turn-off can be expressed by using the structural parameters (d1, β), the physical constant εₛ, and the operating conditions (V_{L}=V_{B}/2, dV/dt=100 kV/μs). Assuming the passage of current with this lave, the SJ-SiC-MOSFET 101 may be designed such that the voltages generated in the BPW regions 31 and the connection regions 34 become low enough, e.g., a value that is approximately below 5V. If the surface resistance is expressed as Rₚₜₒₜ (Ωcm²), the surface resistance being the resistance per unit area of the path over which holes flow from the intersecting regions 92 to the source electrode 80, Rₚₜₒₜ may satisfy the following expression under conditions that dV/dt=100 kV/μs and V_{L}=V_{B}/2.

$$\begin{matrix}Math . 16 & \\ {i}_{ave} * {R}_{p t o t} = ( 4 \times 1 {0}^{11} ) {β}^{2} {d}_{1} {ϵ}_{S} * {R}_{p t o t} < 5 & ( 16 )\end{matrix}$$

If Expression (16) is modified focusing on Rₚₜₒₜ, the following expression is obtained.

$$\begin{matrix}Math . 17 & \\ {R}_{p t o t} < \frac{5}{( 4 \times 1 {0}^{11} ) {β}^{2} {d}_{1} {ϵ}_{S}} & ( 17 )\end{matrix}$$

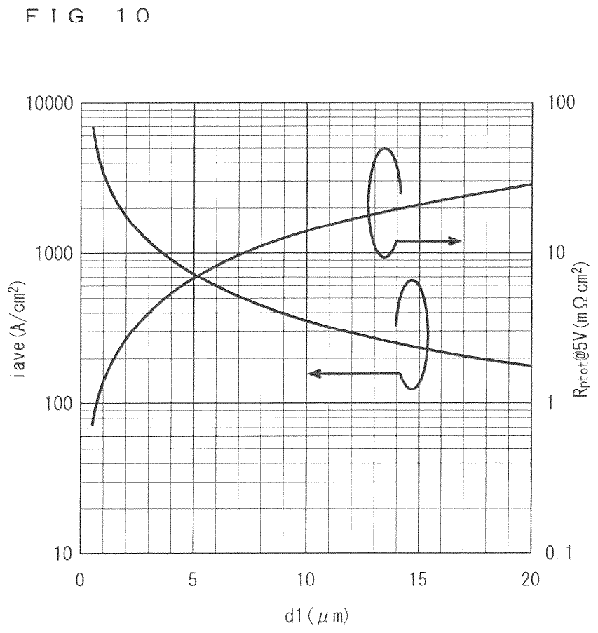

FIG. 10 shows Expressions (15) and (17) in graphical form. In FIG. 10, the horizontal axis represents the pillar pitch d1 in the SJ region 90, and the vertical axes represent the average current density lave and the surface resistance Rₚₜₒₜ of the path over which holes flow from the intersecting regions 92 to the source electrode 80. Based on this assumption (dV/dt=100 kV/μs, V_{L}=V_{B}/2), the SJ-MOSFET optimally designed according to the Fujihira's theory passes the current with the average current density lave shown in FIG. 10. It can be seen from FIG. 10 that the average current density lave has d1 dependence and that a larger transient current flows as the pillar pitch d1 in the SJ region 90 decreases. If d1 is assumed to be approximately 3 μm, the average current density lave becomes a large current that exceeds 1000 A/cm². In the SJ-SiC-MOSFET 101, the second pillar regions 30 have a width 2d of 1 μm to 10 μm. That is, the repetition interval d1 of the second pillar regions 30 is greater than or equal to 2 μm and less than or equal to 20 μm. Under this condition, the desired effects can be achieved if Rₚₜₒₜ at ambient temperature is designed to be less than or equal to 3 mΩcm².

The constituent elements of Rₚₜₒₜ are decomposed in a concrete manner. Referring first to the contact resistance between the body contact regions 33 and the source electrode 80 via the first ohmic contact region 70, Non-Patent Document 2 has already shown the technique that enables acquiring low resistivity of 1×10⁻⁵ Ωcm² to 1×10⁻⁴ Ωcm². Thus, for example, if the area proportion of the area of contact between the first ohmic contact region 70 and the body contact regions 33 in the active region is set to approximately 20%, the contact resistance becomes 0.5 mΩcm² and the contribution of the contact resistance to Rₚₜₒₜ is low enough to be ignorable even if the contact resistivity is set to be a relatively high value such as 1×10⁻⁴ (2 cm².

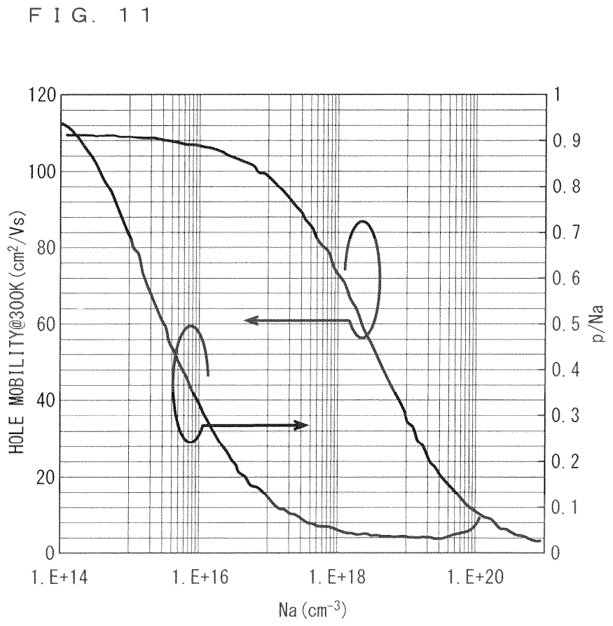

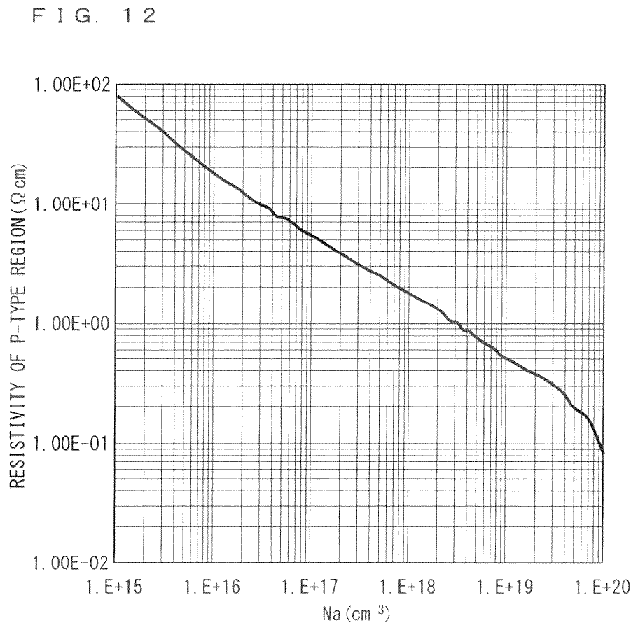

Next, the internal resistance of the p-type regions in the MOSFET region 91 is described. The p-type regions as used herein refer to the body contact regions 33, the body regions 32, the connection regions 34, the BPW regions 31, and the second pillar regions 30. As a challenge unique to SiC, the p-type regions as a whole have low hole mobility and high resistance. This point is discussed quantitatively. First, the hole mobility has concentration dependence. Even if acceptors are properly activated by annealing conducted in the active region, the ionization rate of acceptors are low at ambient temperature because the acceptor level is at a relatively deep position from the valence band. The ionization rate of acceptors refers to the ratio of actual formation of holes to the acceptor impurity concentration. The ionization rate has concentration dependence. Non-Patent Document 3 are referenced to for the concentration dependence of the hole mobility and the ionization rate p/Na. FIG. 11 shows impurity-concentration dependence of the hole mobility and the ionization rate p/Na used for subsequent calculations. The horizontal axis in FIG. 11 represents the acceptor impurity concentration Na (cm⁻³), and the vertical axes represent the hole mobility (cm²/Vs) and the ionization rate p/Na at 300K. FIG. 12 shows the result of calculating the resistivity p of the p-type regions from p=1/qμNaγ on the basis of the concentration dependence of the hole mobility and the ionization rate p/Na shown in FIG. 11. Here, γ is the activation ratio. The horizontal axis in FIG. 12 represents the acceptor impurity concentration Na (cm⁻³), and the vertical axis represents the resistivity ρ (Ωcm) of the p-type regions.

By referring to FIG. 11 as a basis, the fact that the body contact regions 33 and the body regions 32 do not contribute to Rₚₜₒₜ is described. First, the body contact regions 33 are assumed to have a low impurity concentration of 5×10¹⁸ cm⁻³, a relatively great thickness of 1 μm, and a relatively low area proportion of 20% in the active region. Even with this relatively strict assumption, the value of the vertical surface resistance of the body contact regions 33, calculated based on the resistivity in FIG. 11, becomes 0.38 mΩcm² and is low enough to be ignorable. Next, the body regions 32 are assumed to have a relatively low impurity concentration of 5×10¹⁷ cm⁻³, a relatively great thickness of 2 μm, and an area proportion of 80% in the active region. The value of the vertical surface resistance of the body contact regions 33, calculated based on the resistivity in FIG. 11, becomes 0.63 mΩm² and is again low enough to be ignorable. Moreover, the BPW regions 31 do not contribute to longitudinal conduction and has ignorable contribution to Rₚₜₒₜ because the BPW regions 31 are adjacent to the connection regions 34 and have an impurity concentration higher than or equal to the impurity concentration in the body regions 32.

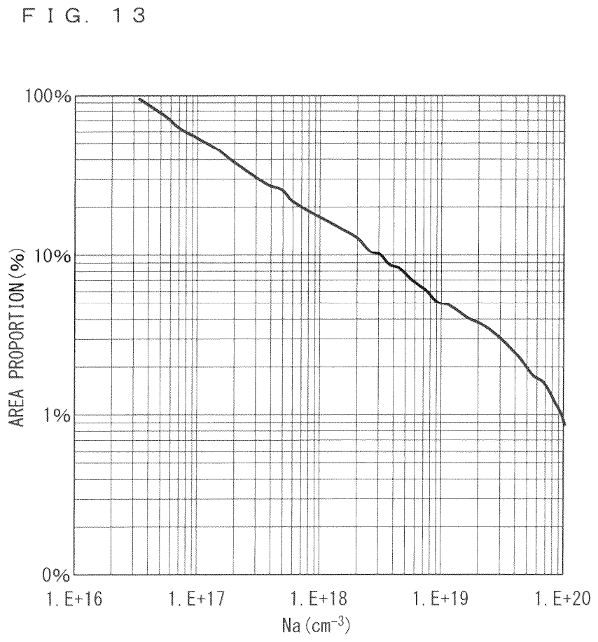

Accordingly, the principal element that gives influence on Rₚₜₒₜ is the resistance of the connection regions 34. The length of the connection regions 34 in the depth direction is assumed to be a relatively large value of 3 μm. On this assumption, the relationship between the impurity concentration Na (cm⁻³) in the connection regions 34 and the area proportion thereof in an xy plane for the case the connection regions 34 generate a voltage of 5V and have resistivity of 3 mΩcm² is calculated based on the result of trial calculation of resistivity in FIG. 12. The result is shown in FIG. 13.

In order to reduce the JFET resistance, the JFET regions 22 in the upper portions of the second pillar regions 30 need to pass a certain amount of current. When the ratio of the width between the second pillar regions 30 and the first pillar regions 21 is 1:1, the area ratio of the second pillar regions 30 in the SJ region 90 in an xy plane is 50%. In this case, if the JFET regions 22 are formed in regions that correspond to the half or more of the tops of the second pillar regions 30 in terms of the area ratio in an xy plane, the least possible effects of the technique according to the present disclosure can be achieved. In this case, the area proportion of the connection regions 34 in the xy plane is 25% or less. Accordingly, it can be said from FIG. 13 that the impurity concentration in the connection regions 34 may be higher than or equal to 4×10¹⁷ cm⁻³. In order to more reliably obtain the effects of the technique according to the present disclosure, it is desirable to further reduce the area proportion of the connection regions 34 in the xy plane. Reducing the area proportion of the connection regions 34 increases the area proportion of the JFET regions 22. As a result, the JFET resistance of the upper portions of the second pillar regions 30 decreases, and also the channel width density that contributes to the passage of the ON-state current increases. For example, if the area proportion of the connection regions 34 is reduced to 10% or less, the effects of the technique according to the present disclosure can be achieved more remarkably. In this case, the impurity concentration in the connection regions 34 may be higher than or equal to 2×10¹⁸ cm⁻³ as can be seen from FIG. 13.

The discussions given thus far are mainly about the conditions for the connection regions 34 that allows smooth passage of current with an average value obtained by dividing the discharging electric charges in the second pillar regions 30 by the voltage rise time. Meanwhile, actual current resulting from the expansion of the depletion layer in the SJ region 90 is not so simple as described above and is nonlinear and complicated. This is due to the fact that the depletion layer capacity of the semiconductor is a variable capacity that depends on the voltage applied. It is, of course, possible to describe rough behaviors of the switching characteristics of the MOSFET in the aforementioned discussion on the average value, and it is possible to design the connection regions 34 based on the rough behaviors. However, in order to more improve performance, more detailed calculations become necessary.

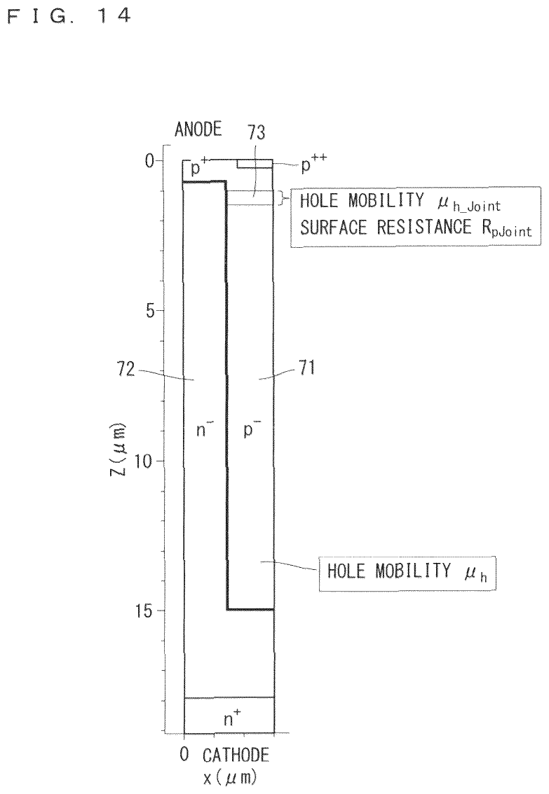

Therefore, current that is allowed to flow during switching in the pn-diode structure where d1=3 μm is obtained by TCAD calculation. FIG. 14 shows the pn-diode structure used in the TCAD calculation. This diode structure includes a p-type pillar region 71 and an n-type pillar region 72. On the top of the p-type pillar region 71, a region 73 in which the hole mobility is locally degraded (hereinafter, also referred to as a mobility degradation region 73) is provided in order to simulate a connection region 34. The hole mobility in the mobility degradation region 73 is expressed as μₕⱼₒᵢₙₜ, and the hole mobility in the other p-type pillar region 71 is expressed as μₕ.

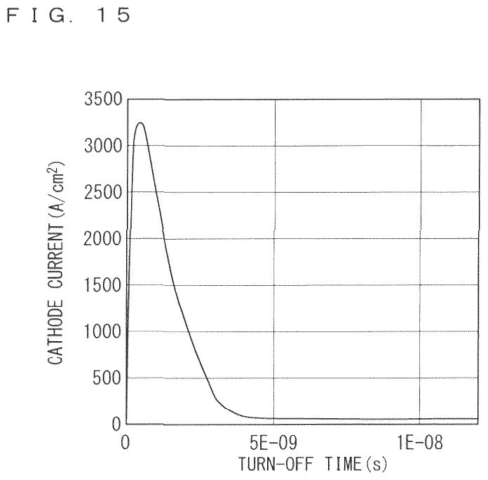

FIG. 15 shows the temporal waveform of current flowing through the cathode when the cathode voltage is increased from 0V up to 1200V where dV/dt=100. The time required for this voltage rise is 1.2×10⁻⁸ seconds, but the cathode current is concentrated in the first half of the voltage rise. This is because, in the early stage where the depletion layer expands in the SJ region 90, the depletion layer capacity is highest due to the small width of the depletion layer, but the depletion layer capacity decreases as the depletion layer expands larger. A peak value of the cathode current is 3250 A/cm², in which case the amount of current flow is two to third times that in the case where d1=3 μm in FIG. 10.

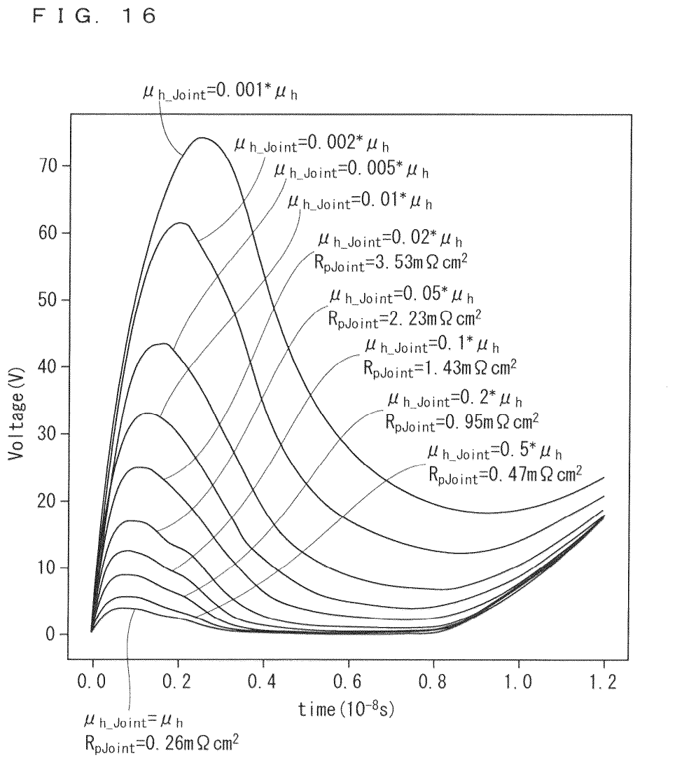

FIG. 16 shows the temporal waveform of the voltage difference between immediately upper and lower portions of the mobility degradation region 73. In FIG. 16, domains ranging from 0.8×10⁻⁸ seconds onwards on the horizontal axis do not necessarily have to be taken into consideration because these domains indicate a voltage rise resulting from depletion of the whole of the mobility degradation region 73. According to the discussions about the average current, sufficient effects are expected if Rₚₜₒₜ is 3 mΩcm² or less, but it can be confirmed from the graph that a voltage exceeding 5V can possibly be induced instantaneously even if the resistance R_{pJoint} of the mobility degradation region 73 that corresponds to Rₚₜₒₜ is 3 mΩcm² or less. This is because the cathode current is concentrated in the expansion start period for the depletion layer in which the depletion layer capacity is high. If R_{pJoint} is reduced to one-third or less, i.e., 1 mΩcm² or less, the voltage to be induced can be suppressed to 5V or less during almost every period, and the effects of the technique according to the present disclosure can be further improved. If R_{pJoint} is reduced to one-tenth or less, i.e., 0.3 mΩcm² or less, the voltage to be induced can be supplied to 5V or less during every period, and the effects of the technique according to the present disclosure can be achieved more than enough.

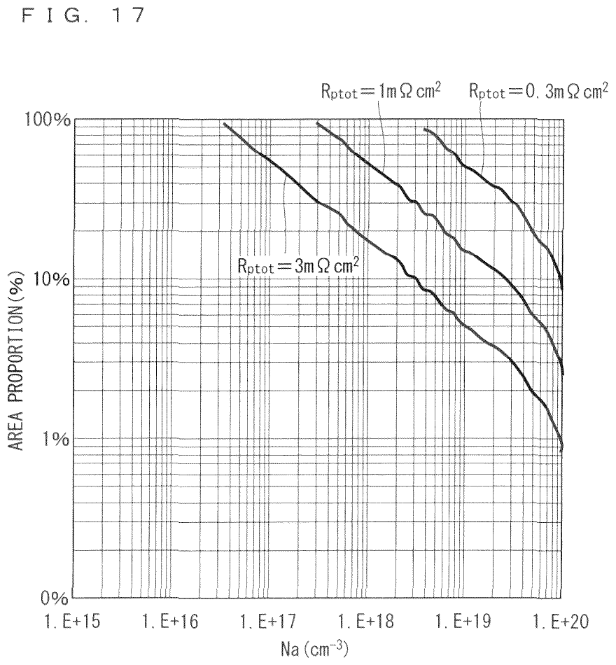

Similarly to FIG. 12, FIG. 17 shows the result of trial calculation of the relationship between the impurity concentration Na (cm⁻³) in the connection regions 34 and the area proportion in an xy plane for the case where the connection regions 34 have resistivity of 1 mΩcm² and 0.3 mΩcm². According to the result shown in FIG. 17, in order to achieve Rₚₜₒₜ=1 mΩcm², if the area proportion of the connection regions 34 is 25%, the acceptor concentration in the connection regions 34 may be set to 4×10¹⁸ cm⁻³. If the area proportion of the connection regions 34 is 10%, the acceptor concentration in the connection regions 34 may be set to 3×10¹⁹ cm⁻³. In order to achieve Rₚₜₒₜ=0.3 mΩcm², the acceptor concentration in the connection regions 34 may be set to 4×10¹⁹ cm⁻³ or higher when the area proportion of the connection regions 34 is 25%. When the area proportion of the connection regions 34 is 10%, the acceptor concentration in the connection regions 34 may be set to 1×10²⁰ cm⁻³.

### A-3-4. Turn-On

Next, turn-on is described from among the switching operations. Turn-on is the operation in which the gate voltage is switched to a voltage greater than or equal to a threshold value, e.g., 15V, from a state in which the load voltage V_{L} is applied to the MOSFET with high resistance so that the n-channel is induced and the MOSFET transitions to the ON state. At this times, the drain current increases rapidly and thereafter the voltage drops to a value in the vicinity of the ON-state voltage.

The transition of the device condition in the turn-on state is described. First, a load voltage V_{L} induced by current I_{L} flowing through a load such as an electric motor is applied to the drain electrode 83. When electric charges are applied from gate terminals by a gate driver, the gate voltage starts to rise. When the gate voltage exceeds a threshold voltage Vth, the resistance of the channel region start to decrease, and the drain current starts to increase. At this time, since the drain voltage remains at V_{L} and the MOSFET operates in the saturation region, the drain current varies depending on the gate voltage. Since the drain voltage remains unchanged at V_{L}, when expressed in terms of circuits, the gate voltage rise at this time is determined by a rate at which positive electric charges are accumulated on the gate side of the gate-source capacitance Cgs. The drain current continues to rise up to the current I_{L} flowing to the load.

If the gate current continues to flow after the increase in the drain current, the drain voltage starts to drop. This is because positive electric charges accumulated by the gate current are consumed in order to compensate for a shrinkage of the depletion layer in the MOSFET. When expressed in terms of circuits, this is because the gate current is consumed by the discharge of the gate-drain capacitance Cgd. During this period, the gate voltage remains unchanged. This period is referred to as the Miller period as in the case of the turn-off operation. If positive electric charges are charged to the gate terminal of the gate-drain capacitance Cgd during the Miller period, it is possible to compensate for space charges accumulated in the depletion layer of the drift layer. As a result, the drain voltage starts to drop. When the drain voltage has dropped low enough, the operation region of the MOSFET changes from the saturation region to the linear region. This causes the gate voltage to further rise and ultimately to be increased up to a prescribed value. Accordingly, the drain voltage drops to the ON-state voltage, and this competes the turn-on operation.

A time quadrature of the product of the drain current and the drain voltage induced during these series of turn-on period is referred to as turn-on loss out of switching loss. In order to reduce the turn-on loss, it is necessary to shorten the Miller period, i.e., to increase the rate of drain voltage drop in a state in which constant current I_{L} flows. In general, reducing Cgd is effective to shorten the Miller period. This point is the same as in the turn-off operation. Therefore, the same discussions can be applied to the rate of voltage change at turn-on, i.e., dV/dt, although the sign of dV/dt at turn-on is reversed from that at the turn-off. Accordingly, the conditions required for the connection regions 34 are the same as those at turn-off, and thus a detailed description thereof shall be omitted. The description given above completes the operations of the SJ-MOSFET.

### A-4. Variations

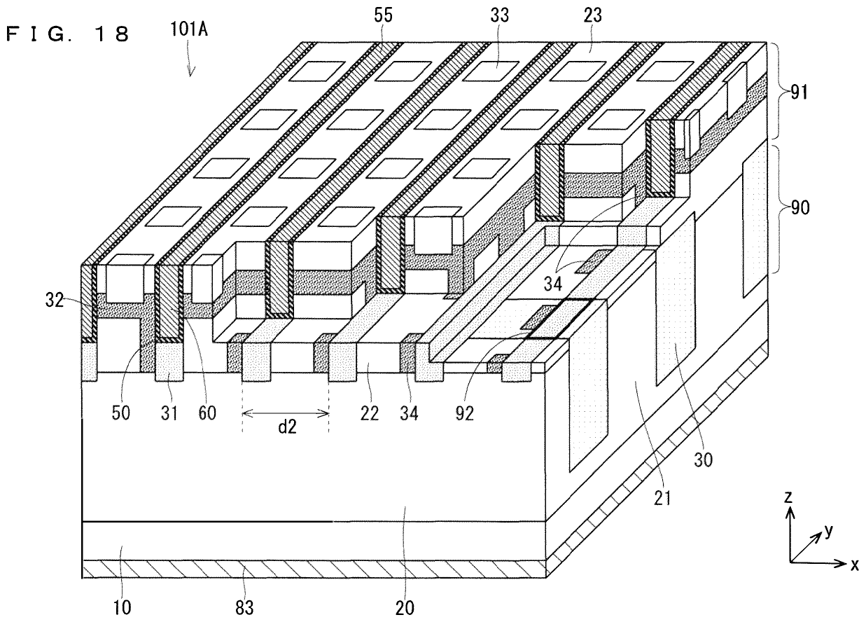

FIG. 18 is a perspective view of a unit cell of an SJ-SiC-MOSFET 101A according to a first variation of Embodiment 1. The SJ-SiC-MOSFET 101A differs from the SJ-SiC-MOSFET 101 in that the p-type connection regions 34 are provided not only in the BPW regions 31 formed on the second pillar regions 30, but also in the BPW regions 31 formed on the upper portions of the first pillar regions 21. That is, the BPW regions 31 on the first pillar regions 21 are connected to the body regions 32 via the connection regions 34. This allows the passage of current that is caused to flow to the BPW regions 31 by variations in the electric field applied to the gate insulating film 50, separately from charging and discharging to and from the SJ pillar. Accordingly, the electric field applied to the gate insulating film 50 is reduced.

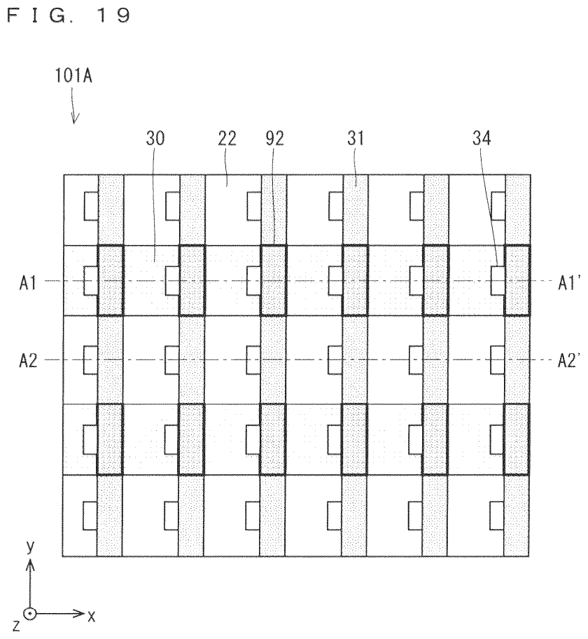

FIG. 19 is a plan view of the SJ-SiC-MOSFET 101A in an xy plane that passes through the intersecting regions 92 between the BPW regions 31 and the second pillar regions 30. As shown in FIG. 19, the connection region 34 are formed not only in contact with the intersecting regions 92 in the BPW regions 31, but also in contact with portions other than the intersecting regions 92.

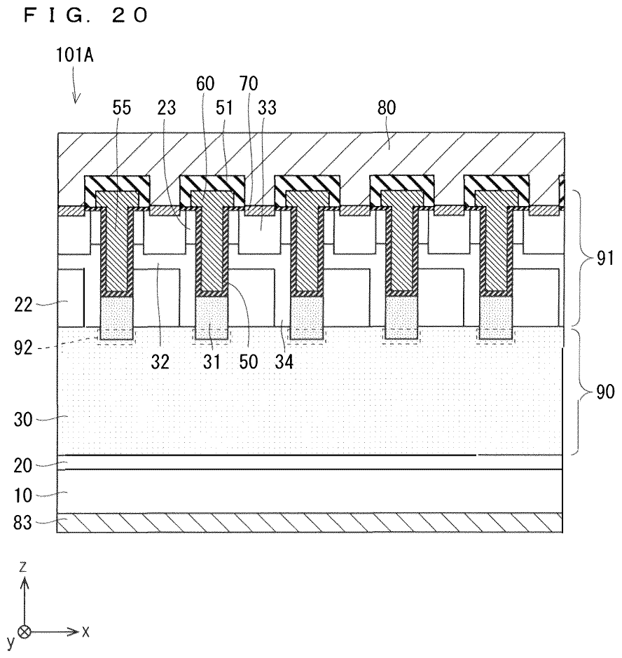

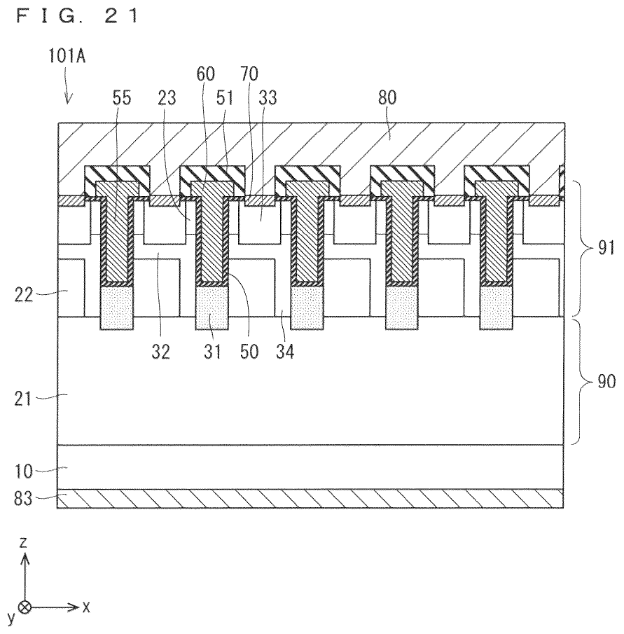

FIG. 20 is a sectional view of the SJ-SiC-MOSFET 101A taken along an A1-A1′ section in FIG. 19. FIG. 20 is similar to FIG. 5. FIG. 21 is a sectional view of the SJ-SiC-MOSFET 101A taken along an A2-A2′ section in FIG. 19.

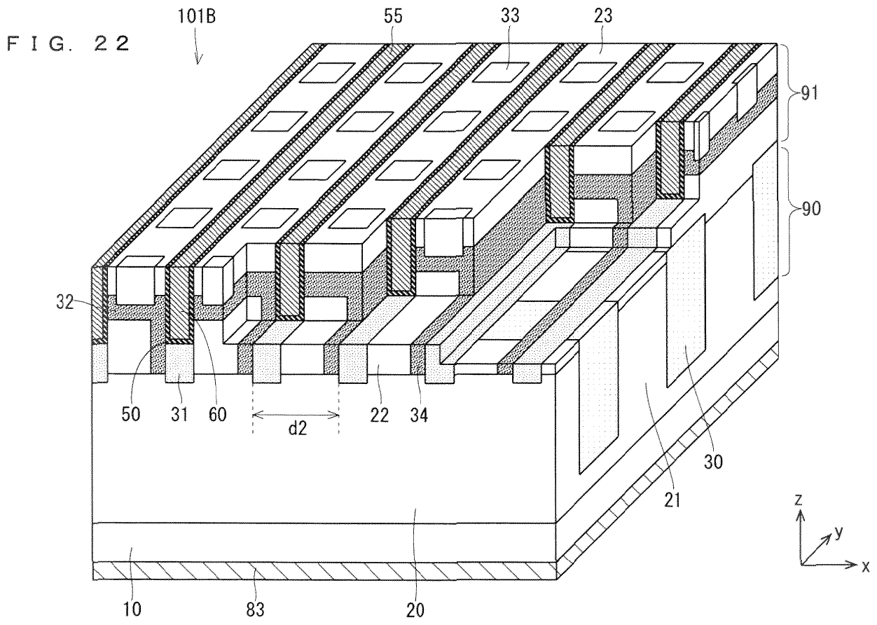

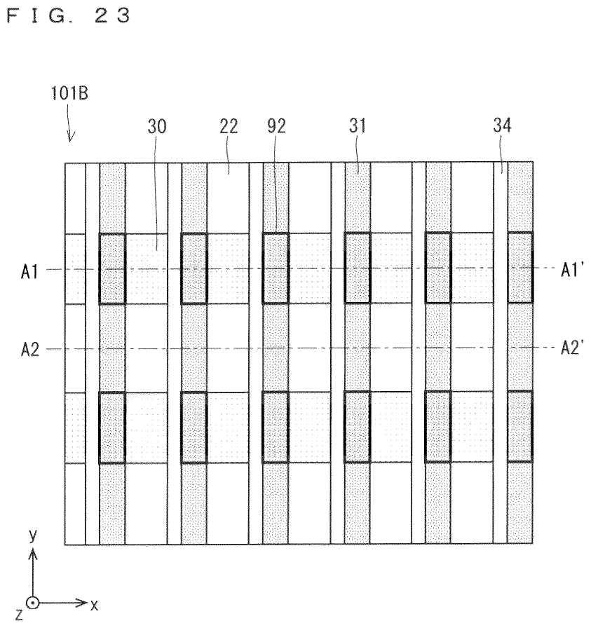

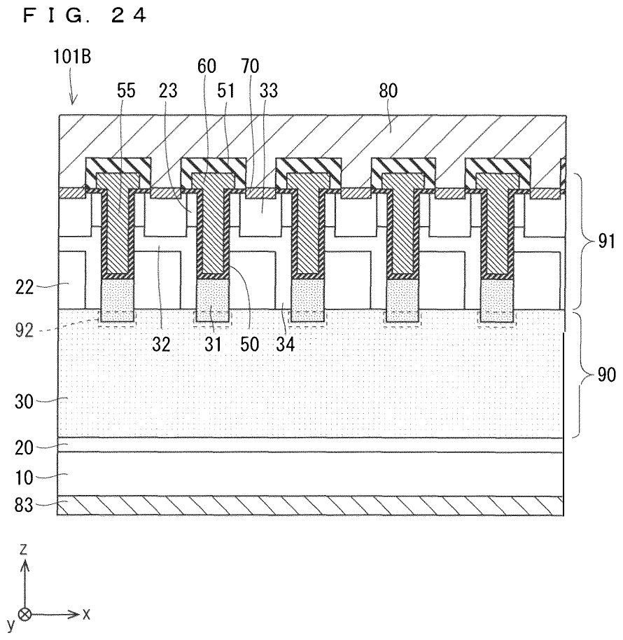

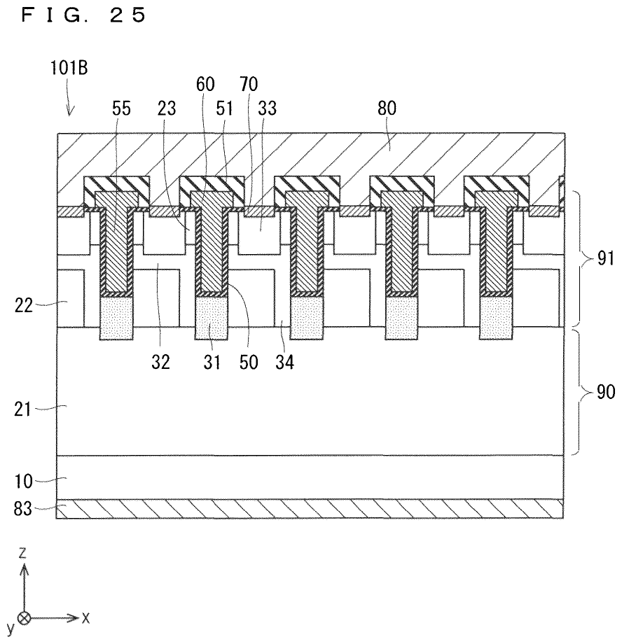

FIG. 22 is a perspective view of a unit cell of an SJ-SiC-MOSFET 101B according to a second variation of Embodiment 1. FIG. 23 is a plan view of the SJ-SiC-MOSFET 101B in an xy plane that passes through the intersecting regions 92 between the BPW regions 31 and the second pillar regions 30. FIG. 24 is a sectional view of the SJ-SiC-MOSFET 101B taken along an A1-A1′ section in FIG. 23. FIG. 25 is a sectional view of the SJ-SiC-MOSFET 101B taken along an A2-A2′ section in FIG. 23.

The SJ-SiC-MOSFET 101B differs from the SJ-SiC-MOSFET 101 in that the connection regions 34 that connect the body regions 32 and the BPW regions 31 are provided on the entire side surface on one side of each trench 55. FIGS. 22 to 25 illustrate a configuration in which the connection regions 34 are provided on a side surface on the negative side of each trench 55 in the x axial direction.

This configuration reduces the channel width density and thus increases the channel resistance, but instead reduces the saturation current density and increases tolerance to short-circuiting. Besides, the electric field applied to the gate insulating film 50 decreases because connection resistance to the second pillar regions 30 decreases. Moreover, it is possible to minimize an increase in JFET resistance and to use a current path passing over the second pillar regions 30. According, the effects of the technique according to the present disclosure can be achieved enough.

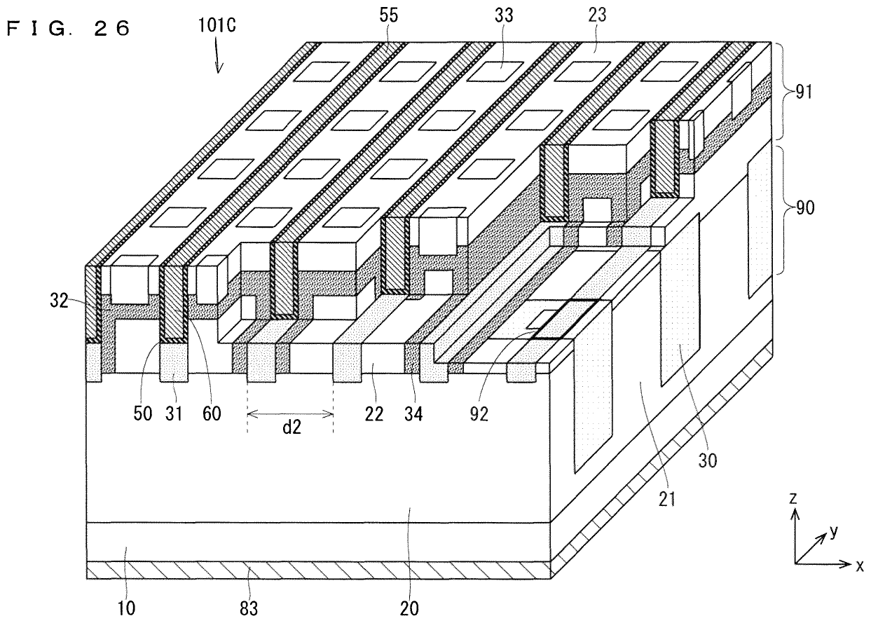

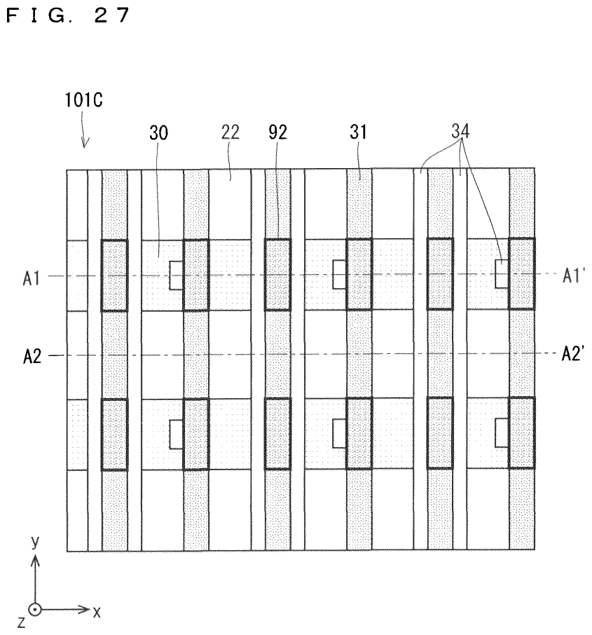

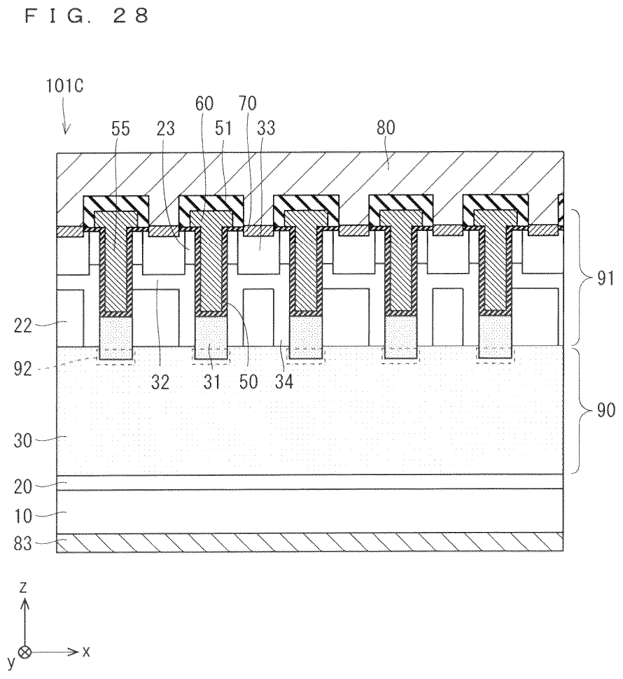

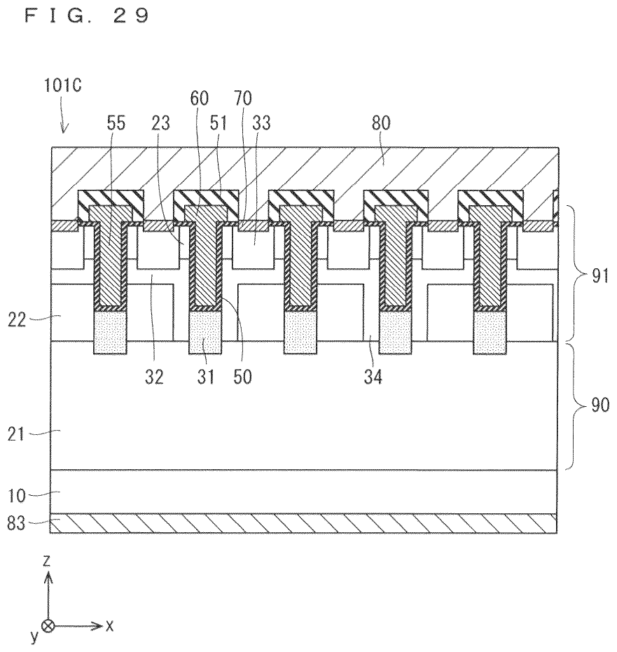

FIG. 26 is a perspective view of a unit cell of an SJ-SiC-MOSFET 101C according to a third variation of Embodiment 1. FIG. 27 is a plan view of the SJ-SiC-MOSFET 101C in an xy plane that passes through the intersecting regions 92 between the BPW regions 31 and the second pillar regions 30. FIG. 28 is a sectional view of the SJ-SiC-MOSFET 101C taken along an A1-A1′ section in FIG. 27. FIG. 29 is a sectional view of the SJ-SiC-MOSFET 101C taken along an A2-A2′ section in FIG. 27.

The SJ-SiC-MOSFET 101C differs from the SJ-SiC-MOSFET 101 in that two different types of trenches 55 are alternately arranged, specifically, trenches 55 that include the connection regions 34 provided on the entire side surfaces on both sides and trenches 55 that do not include the connection regions 34 in any region other than in the vicinity of the intersecting regions 92. In other words, the connection regions 34 are formed on the entire side surfaces on both sides of some trenches 55 and formed only at the intersections between the BPW regions 31 and the second pillar regions 30 under the other trenches 55.

As in the case of the SJ-SiC-MOSFET 101B, this configuration reduces the channel width density and accordingly increases the channel resistance, but instead reduces the saturation current density and accordingly increases tolerance to short-circuiting. Moreover, the electric field applied to the gate insulating film 50 is reduced because the connection resistance to the second pillar regions 30 decreases. Moreover, it is possible to minimize an increase in JFET resistance and to use the current-carrying path over the second pillar regions 30. Accordingly, the effects of the technique according to the present disclosure can be achieved enough.

In the SJ-SiC-MOSFET 101C, the trenches 55 whose both side walls are covered with the connection regions 34 do not contribute to static characteristics of the transistor. Thus, the gate electrodes 60 formed in these trenches 55 may be maintained in a floating state without being connected to the gate line 82. Moreover, the gate electrodes 60 formed in these trenches 55 may be connected to the source electrode 80 and used as dummy trench gates. In this case, the gate input capacitance can be reduced by almost one-half from the viewpoint of the whole of the MOSFET. Accordingly, it is possible to increase the rate of switching that can be operated by the same gate driver, i.e., dV/dt and dI/dt, and hereby to achieve the MOSFET capable of high-speed operations.

In the SJ-SiC-MOSFET 101C, the repetition interval of the trenches 55 does not necessary have to be constant at 1:1 and may, for example, be 2:3 or 1:5. By changing the repetition interval, a tradeoff between the gate input capacitance and the ON-state resistance may be adjusted to provide an optimum mode.

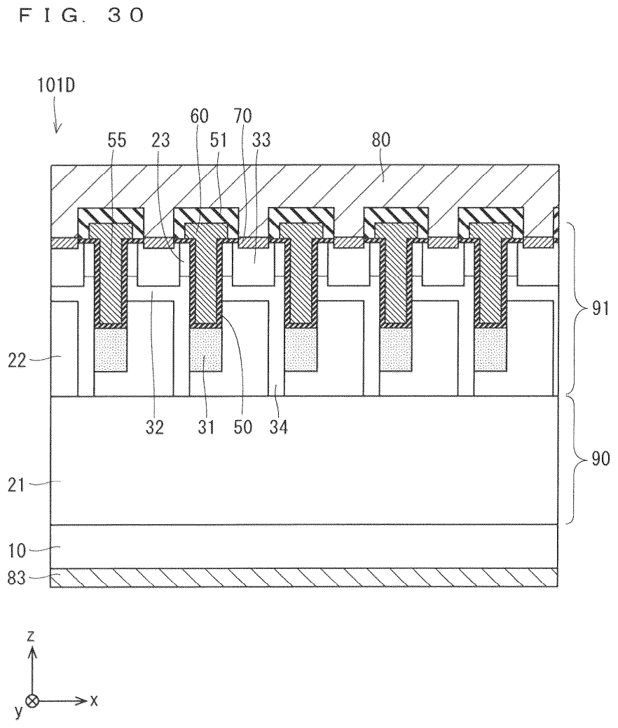

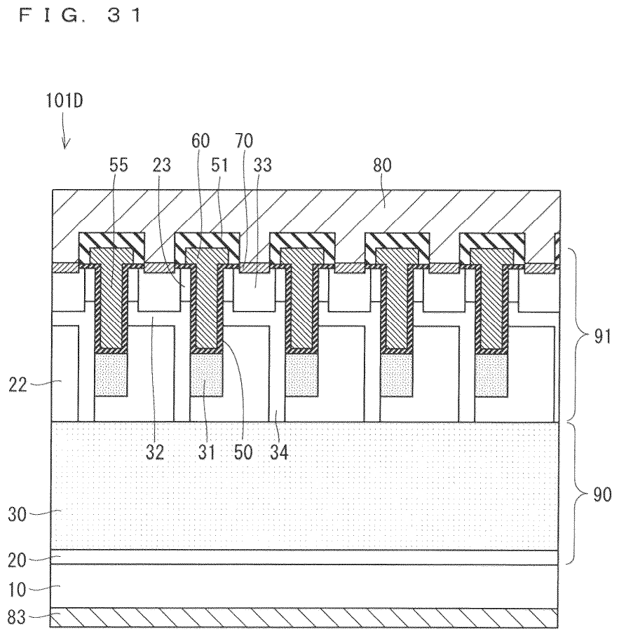

FIGS. 30 and 31 are sectional views of an SJ-SiC-MOSFET 101D according to a fourth variation of Embodiment 1. FIG. 30 is a sectional view in an xz plane that passes through the first pillar regions 21. FIG. 31 is a sectional view in an xz plane that passes through the second pillar regions 30. The SJ-SiC-MOSFET 101D differs from the SJ-SiC-MOSFET 101B according to the second variation, in that the first pillar regions 21 and the second pillar regions 30 are not directly connected to the BPW regions 31, but connected via the connection regions 34 to the BPW regions 31.

### A-5. Advantageous Effects

The SJ-SiC-MOSFET 101, which is the silicon carbide semiconductor device according to Embodiment 1, includes the n-type silicon carbide substrate 10, the SJ region 90 formed of silicon carbide, and the MOSFET region 91 provided on the upper surface of the SJ region 90. The silicon carbide substrate 10 has first and second main surfaces opposed to each other. The SJ region 90 is provided on the first main surface of the silicon carbide substrate 10. The SJ region 90 include the plurality of n-type first pillar regions 21 and the p-type second pillar regions 30 that extend in the x axial direction, which is the first direction parallel to the first main surface, and that are alternately aligned in the y axial direction, which is the second direction parallel to the first main surface and perpendicular to the first direction. The MOSFET region 91 includes the plurality of BPW regions 31 formed of p-type silicon carbide, the plurality of gate electrodes 60, the plurality of JFET regions 22 formed of n-type silicon carbide, the plurality of body regions 32 formed of p-type silicon carbide, the plurality of body contact regions 33 formed of p-type silicon carbide, the source region 23 that includes a plurality of impurity regions formed of n-type silicon carbide, and at least one connection region 34 formed of p-type silicon carbide. The BPW regions 31 each extend in the y axial direction and are aligned at the second repetition interval d2 and connected to the second pillar regions30, the second repetition interval d2 being shorter than the first repetition interval d1, which is the repetition interval of the second pillar regions 30. Each gate electrode 60 is provided via the gate insulating film 50 in each trench 55 provided in the y axial direction above each BPW region 31. Each JFET region 22 extends in the y axial direction between two adjacent BPW regions 31 and between two adjacent trenches 55. Each body region 32 is provided on and in contact with each JFET region 22. Each body contact region 33 is provided on each body region 32 and has lower resistivity than each body region 32. The source region 23 is provided in contact with each trench 55 and each body contact region 33 on each body region 32. At least one connection region 34 is in contact with at least one of the JFET regions 22 and connects at least one of the BPW regions 31 and at least one of the body regions 32. The SJ-SiC-MOSFET 101 includes the source electrode 80, which is the top electrode provided on each body contact region 33, and the drain electrode 83, which is the bottom electrode provided on the second main surface of the silicon carbide substrate 10. The above-described configuration achieves low-resistance contact with the second pillar regions 30, reduces variations in withstand voltage, and reduces the channel resistance and the JFET resistance.

### B. Embodiment 2

### B-1. Configuration

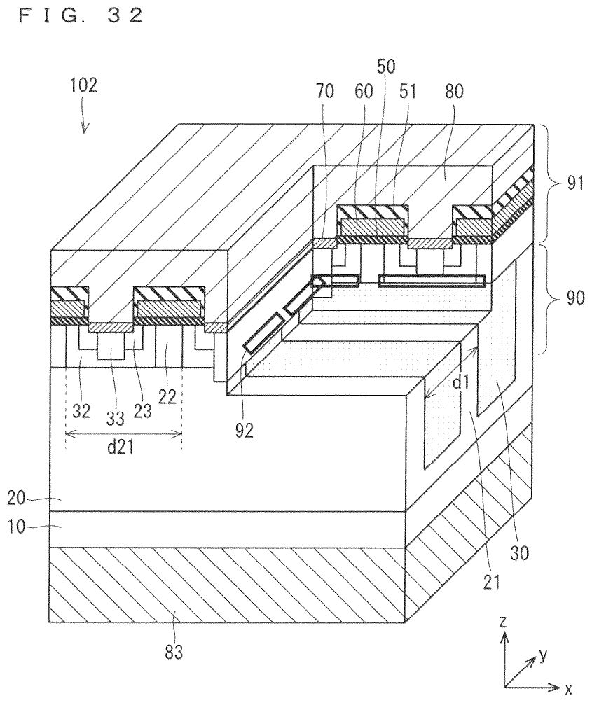

FIG. 32 is a perspective view of a unit cell of an SJ-SiC-MOSFET 102 according to Embodiment 2. While the SJ-SiC-MOSFET 101 according to Embodiment 1 is a trench MOSFET, the SJ-SiC-MOSFET 102 is a planar MOSFET. That is, the SJ-SiC-MOSFET 102 is obtained by applying the characteristic configuration of the SJ-SiC-MOSFET 101 described in Embodiment 1 to a planar MOSFET.

The SJ-SiC-MOSFET 102 differs from the SJ-SiC-MOSFET 101 only in the configuration of the MOSFET region 91. Hereinafter, the MOSFET region 91 of the SJ-SiC-MOSFET 102 is described.

P-type body regions 32 and n-type JFET regions 22 are alternately arranged on the SJ region 90. The body regions 32 extend in the y axial direction and are arranged at a repetition interval d21 in the x axial direction. While, in Embodiment 1, the repetition interval d2 of the BPW regions 31 is referred to as the second repetition interval in Embodiment 1, the repetition interval d21 of the body regions 32 is referred to as the second repetition interval in Embodiment 2. The repetition interval d21 of the body regions 32 is shorter than the repetition interval d1 of the second pillar regions 30. The JFET regions 22 are arranged between the body regions 32. N-type source regions 23 are formed in the surface layers of the body regions 32. P-type body contact regions 33 extend from the upper surfaces of the source regions 23 through the source regions 23 to the body regions 32. The surface layers of the body regions 32 sandwiched between the JFET regions 22 and the source regions 23 are defined as channel regions. Gate electrodes 60 are formed on the channel regions and the JFET region 22 via the gate insulating film 50. The foregoing is the configuration of the MOSFET region 91.

The gate electrodes 60 are covered with the interlayer insulation film 51 and insulated from the source electrode 80. The gate insulating film 50 and the interlayer insulation film 51 have contact holes. The source electrode 80 is formed inside the contact holes and on the interlayer insulation film 51. The source electrode 80 has ohmic contact with the body contact regions 33 and the source regions 23 via the first ohmic contact region 70 inside the contact holes.

Unlike in the SJ-SiC-MOSFET 101, the MOSFET region 91 of the SJ-SiC-MOSFET 102 does not include the trenches 55, the BPW regions 31, and the connection regions 34. The body regions 32 that have a relatively high concentration are directly connected to the second pillar regions 30. Intersections between the body regions 32 and the second pillar regions 30 make the intersecting regions 92. Thus, the surface resistance Rₚₜₒₜ in the path over which holes flow from the intersecting regions 92 to the source electrode 80 is suppressed to a low value. Accordingly, it is possible to achieve the effects of the technique according to the present disclosure to some extent without adding any special structure.

### B-2. Manufacturing Method

A method of manufacturing the SJ-SiC-MOSFET 102 is almost similar to the method of manufacturing the SJ-SiC-MOSFET 101 described in Embodiment 1. Steps until the n-type epitaxial region is grown after the formation of the SJ region 90 on the silicon carbide substrate 10 are similar to those in Embodiment 1. Thereafter, the steps of forming the body regions 32, the JFET regions 22, the source region 23, and the body contact regions 33 by photolithography, ion implantation, and activation annealing are also similar to those in Embodiment 1, although the structure is different. The present method does not include the trench etching step and the steps of forming the BPW regions 31 and the connection regions 34. Thereafter, the high-quality gate insulating film 50 is formed by thermal oxidation. The subsequent steps are similar to those in Embodiment 1.

### B-3. Variations

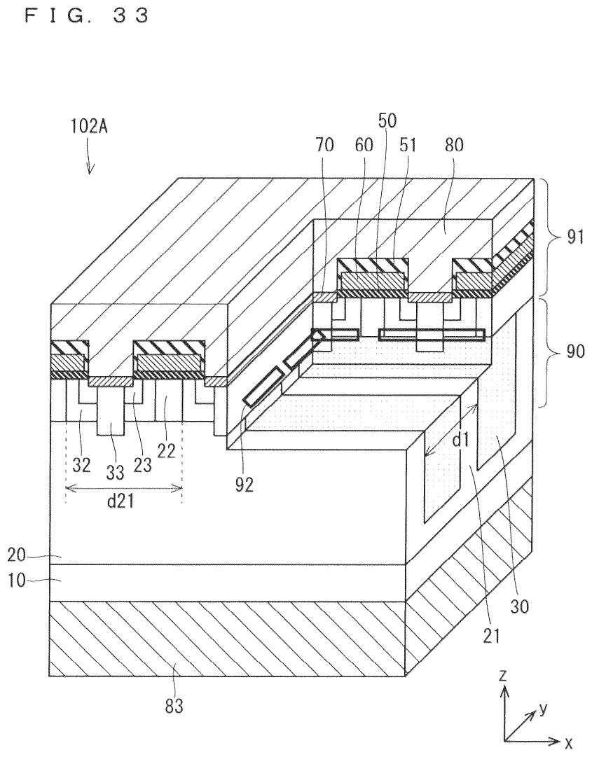

FIG. 33 is a perspective view of an SJ-SiC-MOSFET 102A according to a first variation of Embodiment 2. The SJ-SiC-MOSFET 102A differs from the SJ-SiC-MOSFET 102 in that the body contact regions 33 penetrate the body regions 32 and reach the SJ region 90. In this configuration, the body contact regions 33 also function as the connection regions 34 that connect the second pillar regions 30 and the body regions 32 according to Embodiment 1. Since the second pillar regions 30 and the body regions 32 are connected by the body contact regions 33 having a high p-type impurity concentration, it is possible to reduce the surface resistance Rₚₜₒₜ in the path over which holes flow from the second pillar regions 30 to the source electrode 80. As a result, an electric field applied to the gate insulating film 50 can be reduced.

Note that the body contact regions 33 may have different impurity concentrations between their upper portions and their lower portions that come in contact with the SJ region 90, or may have a uniform impurity concentration.

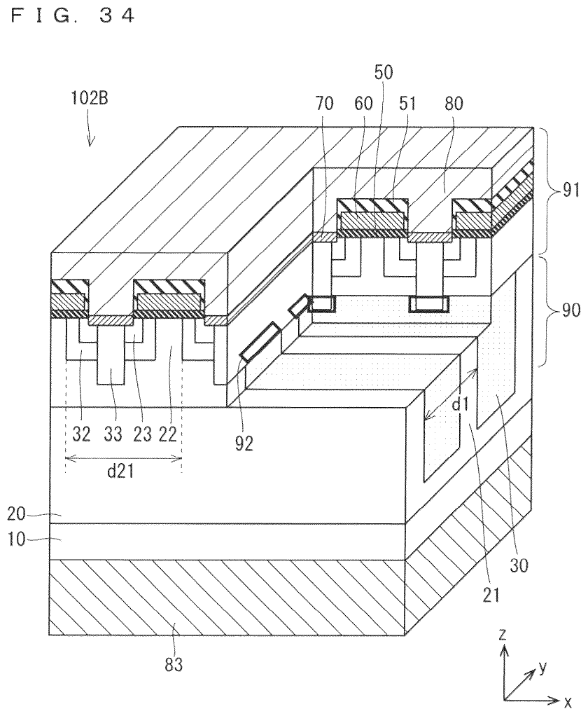

FIG. 34 is a perspective view of a unit cell of an SJ-SiC-MOSFET 102B according to a second variation of Embodiment 2. In the SJ-SiC-MOSFET 102B, the body regions 32 and the second pillar regions 30 are not connected to each other. Meanwhile, the body contact regions 33 penetrate the body region 32 and protrude from the lower surfaces of the body regions 32 so as to be connected to the second pillar regions 30 and form the intersecting regions 92. That is, the lower portions of the body contact regions 33 that protrude from the lower surfaces of the body regions 32 function as the connection regions 34 according to Embodiment 1.

The lower portions of the body contact regions 33 have a strip shape and are adjacent to the JFET regions 22. This configuration reduces switching loss because the body regions 32 and the second pillar regions 30 are connected by the body contact regions 33 having a high impurity concentration. Since the lower portions of the body contact regions 33 that function as the connection regions 34 are adjacent to the JFET regions 22, it is possible to reduce the JFET resistance and further reduce the ON-state resistance. Note that the body contact regions 33 may have different impurity concentrations between their upper portions and their lower portions that come in contact with the JFET regions 22, or may have a uniform impurity concentration.

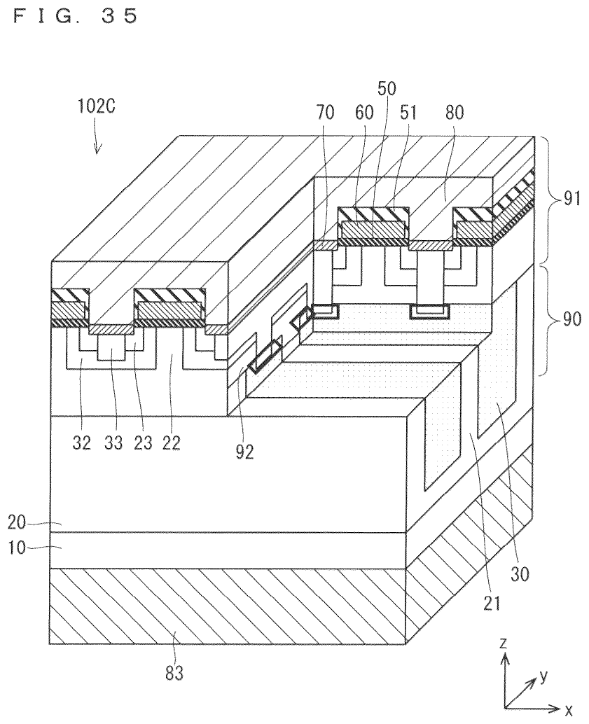

FIG. 35 is a perspective view of a unit cell of an SJ-SiC-MOSFET 102C according to a third variation of Embodiment 2. In the SJ-SiC-MOSFET 102C, the body contact regions 33 protrude from the lower surfaces of the body regions 32 only above the second pillar regions 30 so as to be connected to the second pillar regions 30 and form the intersecting regions 92. Above the first pillar regions 21, the body contact regions 33 do not protrude from the lower surfaces of the body regions 32. In the other points, the SJ-SIC-MOSFET 102C is similar in configuration to the SJ-SiC-MOSFET 102B.

This configuration reduces the ON-state resistance because the JFET regions 22 have a higher area proportion in an xy plane than in SJ-SiC-MOSFET 102B. Besides, as in the case of the SJ-SiC-MOSFET 102B, Rₚₜₒₜ can be suppressed to a low value because the body regions 32 and the second pillar regions 30 are connected by the body contact regions 33 having a high impurity concentration. Note that the body contact regions 33 may have different impurity concentrations between their upper portions and their lower portions that come in contact with the JFET regions 22, or may have a uniform impurity concentration.

In the descriptions of Embodiments 1 and 2, the MOSFET region 91 and the SJ region 90 are connected to each other in every intersecting region 92. However, if Rₚₜₒₜ is uniform as a whole in the active region and is also suppressed to a low value when viewed in a microscopic leave, the MOSFET region 91 and the SJ region 90 do not necessarily have to be connected to each other in every intersecting region 92, and may be connected to each other in, for example, 80% of the intersecting regions 92 either directly or via the connection regions 34 or the body contact regions 33. In this case, the ON-state resistance may be further reduced by a method such as forming the JFET regions 22 in the intersecting regions 92 in which the MOSFET region 91 and the SJ region 90 are not connected to each other.

While Embodiments 1 and 2 have described SJ-SiC-MOSFETs as examples of the silicon carbide semiconductor device having an SJ structure and an MOSFET structure, the technique according to the present disclosure is also applicable to devices such as IGBTs other than MOSFETs. In this case, the emitter electrode, the collector electrode, and the emitter region are used instead of the source electrode, the drain electrode, and the source region. Also, a p-type collector layer is provided between the silicon carbide substrate 10 and the drain electrode.

### B-4. Advantageous Effects

The SJ-SiC-MOSFET 102, which is the silicon carbide semiconductor device according to Embodiment 2, includes the n-type silicon carbide substrate 10, the SJ region 90 formed of silicon carbide, and the MOSFET region 91 provided on the upper surface of the SJ region 90. The silicon carbide substrate 10 has first and second main surfaces opposed to each other. The SJ region 90 is provided on the first main surface of the silicon carbide substrate 10. The SJ region 90 includes the plurality of n-type first pillar regions 21 and the plurality of p-type second pillar regions 30 that extend in the x axial direction, which is the first direction parallel to the first main surface, and are alternately aligned in the y axial direction, which is the second direction parallel to the first main surface and perpendicular to the first direction. The MOSFET region 91 includes the plurality of body regions 32 formed of p-type silicon carbide, the plurality of JFET regions 22 formed of n-type silicon carbide, the source region 23 that includes a plurality of impurity regions formed of n-type silicon carbide, the plurality of body contact regions 33 formed of p-type silicon carbide, and the plurality of gate electrodes 60 provided via the gate insulating film 50 on each body region 32 between each source region 23 and each JFET region 22. The body regions 32 each extend in the y axial direction and are aligned in the x axial direction at the second repetition interval d21 shorter than the first repetition interval d1 of the second pillar region 30 and connected to the second pillar regions. Each JFET region 22 is provided between the body regions 32. Each source region 23 is provided in the surface layer of each body region 32. Each body contact region 33 penetrates each source region 23 from the upper surface of the source region 23 to reach each body region 32 and has lower resistivity than each body region 32. The plurality of gate electrodes 60 are provided via the gate insulating film 50 on each body region 32 between each source region 23 and each JFET region 22. The SJ-SiC-MOSFET 102 includes the source electrode 80, which is the top electrode provided on the plurality of body contact regions 33, and the drain electrode 83, which is the bottom electrode formed on the second main surface of the silicon carbide substrate 10. The above-described configuration achieves low-resistance contact with the second pillar regions 30, reduces variations in withstand voltage, and reduces the channel resistance and the JFET resistance.

### C. Embodiment 3

The present embodiment applies the silicon carbide semiconductor device according to either Embodiments 1 or 2 described above to an electric power converter. Although the application of the silicon carbide semiconductor device according to Embodiment 1 or 2 is not limited to a specific electric power converter, the following description is given of a case in which the silicon carbide semiconductor device according to Embodiment 1 or 2 is applied to a three-phase inverter, as Embodiment 3.

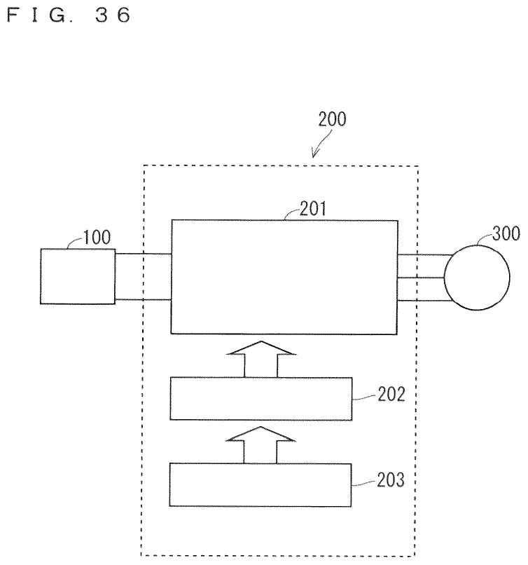

FIG. 36 is a block diagram showing a configuration of an electric power conversion system that applies the electric power converter according to the present embodiment.

The electric power conversion system shown in FIG. 36 includes a power supply 100, an electric power converter 200, and a load 300. The power supply 100 is a DC power supply and supplies direct-current power to the electric power converter 200. The power supply 100 may be configured as a variety of devices. For example, the power supply 100 may be configured as a direct-current system, a solar cell, or an electrical storage battery, or may be configured as an AC/DC converter or a rectifier circuit connected to an alternating-current system. The power supply 100 may also be configured as a DC/DC converter that converts DC power output from a direct-current system into predetermined electric power.

The electric power converter 200 is a three-phase inverter that is connected between the power supply 100 and the load 300, and converts DC power supplied from the power supply 100 into AC power and supply the AC power to the load 300. As shown in FIG. 36, the electric power converter 200 includes a main conversion circuit 201 that converts DC power into AC power and outputs the AC power, a driving circuit 202 that outputs drive signals for driving each switching element of the main conversion circuit 201, and a control circuit 203 that outputs control signals for controlling the driving circuit 202 to the driving circuit 202.

The load 300 is a three-phase electric motor that is driven by AC power supplied from the electric power converter 200. Note that the load 300 is not limited to being applied for specific usage, and may be an electric motor mounted on a variety of electrical apparatuses and may be used as, for example, an electric motor for a hybrid automobile, an electric automobile, a railway vehicle, an elevator, or an air-conditioning equipment.

Hereinafter, details of the electric power converter 200 is described. The main conversion circuit 201 includes switching elements and reflux diodes (not shown) and converts DC power supplied from the power supply 100 into AC power and supplies the AC power to the load 300 by switching of the switching elements. Although there are a variety of specific circuit configurations for the main conversion circuit 201, the main conversion circuit 201 according to the present embodiment may be a two-level three-phase full-bridge circuit and configured by six switching elements and six reflux diodes that are connected in inverse parallel with the switching elements. Each switching element of the main conversion circuit 201 adopts the silicon carbide semiconductor device according to either of Embodiments 1 and 2 described above. Each two of the six switching elements are connected in series and constitute upper and lower arms, and each pair of upper and lower arms constitutes each phase (i.e., U phase, V phase, or W phase) of the full-bridge circuit. The output terminals of each pair of upper and lower arms, i.e., three output terminals of the conversion circuit 201, are connected to the load 300.

The driving circuit 202 generates driving signals for driving the switching elements of the conversion circuit 201 and supplies the driving signals to the control electrodes of the switching elements of the conversion circuit 201. Specifically, the driving circuit 202 outputs a driving signal for turning a switching element on or a driving signal for turning a switching element off to the control electrode of each switching element, in accordance with the control signal output from the control circuit 203, which will be described later. In the case where a switching element is maintained in the ON state, the driving signal is a voltage signal (ON-state signal) higher than or equal to a threshed voltage of the switching element, and in the case where a switching element is maintained in the OFF state, the driving signal is a voltage signal (OFF-state signal) less than or equal to the threshold voltage of the switching element.

The control circuit 203 controls the switching elements of the conversion circuit 201 so that the desired electric power is supplied to the load 300. Specifically, the control circuit 203 calculates time (turn-on time) when each switching element of the conversion circuit 201 is to be turned on, in accordance with the electric power to be supplied to the load 300. For example, the control circuit 203 is capable of controlling the main conversion circuit 201 by PWM control in which the turn-on time of each switching element is modulated in accordance with the voltage to be output. Then, the control circuit 203 outputs control commands (i.e., control signals) to the driving circuit 202 so that an ON-state signal is output to a switching element that is to be turned on, and an OFF-state signal is output to a switching element that is to be turned off at each point in time. In accordance with these control signals, the driving circuit 202 outputs either a ON-state signal or an OFF-state signal as a driving signal to the control electrode of each switching element.

The electric power converter according to the present embodiment improves reliability and conversion efficiency because the silicon carbide semiconductor device according to Embodiment 1 or 2 is adopted as the switching elements of the main conversion circuit 201.

While the present embodiment has described an example of applying the silicon carbide semiconductor device according to Embodiment 1 or 2 to a two-level three-phase inverter, the application of the silicon carbide semiconductor device according to Embodiment 1 or 2 is not limited to this example, and the silicon carbide semiconductor device according to Embodiment 1 or 2 is applicable to a variety of electric power converters. While the present embodiment has described a two-level electric power converter by way of example, the electric power converter may be a three-level or multi-level electric power converter, or may a single phase inverter when power is supplied to a single-phase load. When electric power is supplied to, for example, a DC load, the silicon carbide semiconductor device according to Embodiment 1 or 2 may be applied to a DC/DC converter or an AC/DC converter.

The electric power converter adopting the silicon carbide semiconductor device according to Embodiment 1 or 2 is not limited to being applied to the case where the aforementioned load is an electric motor, and may be used as, for example, a power supply device for an electric spark machine, a laser beam machine, an induction heating cooking appliance, or a non-contact power dispatching system, and may also be used as a power conditioner for systems such as a photovoltaic power generating system or a condensing system.

While the invention has been shown and described in detail, the foregoing description is in all aspects illustrative and not restrictive. It is therefore to be understood that numerous modifications and variations can be devised without departing from the scope of the invention.

### REFERENCE SIGNS LIST

10 silicon carbide substrate
20 drift layer
21 first pillar region
22 JFET region
23 source region
30 second pillar region
31 BPW region
32 body region
33 body contact region
34 connection region
50 gate insulating film
51 interlayer insulation film
55 trench
60 gate electrode
70 first ohmic contact region
71 p-type pillar region
72 n-type pillar region
73 mobility degradation region
80 source electrode
81 source pad
82 gate line
83 drain electrode
90 SJ region
91 MOSFET region
92 intersecting region
100 power supply
200 electric power converter
201 main conversion circuit
202 driving circuit
203 control circuit
300 load

1. A silicon carbide semiconductor device comprising:
an n-type silicon carbide substrate having a first main surface and a second main surface that are opposed to each other;
an SJ region formed of silicon carbide and provided on the first main surface of the silicon carbide substrate; and
an MOSFET region provided on an upper surface of the SJ region,
wherein the SJ region includes a plurality of n-type first pillar regions and a plurality of p-type second pillar regions that extend in a first direction parallel to the first main surface and that are alternately aligned in a second direction parallel to the first main surface and perpendicular to the first direction, and
the MOSFET region includes:
a plurality of BPW regions formed of p-type silicon carbide, extending in the second direction, and aligned in the first direction at a second repetition interval that is shorter than a first repetition interval that is a repetition interval of the plurality of second pillar regions; and
a plurality of gate electrodes provided via a gate insulating film in a plurality of trenches, respectively, that are provided in the second direction above the plurality of BPW regions, respectively.

2.-17. (canceled)

18. The silicon carbide semiconductor device according to claim 1, wherein
the plurality of BPW regions are connected to the plurality of second pillar regions.

19. The silicon carbide semiconductor device according to claim 1, wherein
the MOSFET region includes:
a plurality of JFET regions formed of n-type silicon carbide and extending in the second direction between each adjacent two of the plurality of BPW regions and between each adjacent two of the plurality of trenches:
a plurality of body regions formed of p-type silicon carbide and provided on and in contact with the plurality of JFET regions, respectively; and
at least one connection region formed of p-type silicon carbide, provided in contact with at least one of the plurality of JFET regions, and connecting at least one of the plurality of BPW regions and at least one of the plurality of body regions.

20. The silicon carbide semiconductor device according to claim 1, wherein
the MOSFET region includes:
a plurality of body contact regions formed of p-type silicon carbide, provided on the plurality of body regions, respectively, and having lower resistivity than the plurality of body regions; and
a plurality of impurity regions formed of n-type silicon carbide and provided on the plurality of body regions, respectively, in contact with the plurality of trenches and the plurality of body contact regions, respectively,
the silicon carbide semiconductor device further comprising:
a top electrode provided on each of the plurality of body contact regions; and
a bottom electrode provided on the second main surface of the silicon carbide substrate.

21. The silicon carbide semiconductor device according to claim 1, wherein
each of the plurality of second pillar regions and each of the plurality of BPW regions are directly connected to each other.

22. The silicon carbide semiconductor device according to claim 19, wherein
the at least one connection region includes a plurality of connection regions that are in contact with the plurality of JFET regions, respectively, and that connect each of the plurality of BPW regions and each of the plurality of body regions, and
each of the plurality of second pillar regions and each of the plurality of BPW regions are connected via each of the plurality of connection regions.

23. The silicon carbide semiconductor device according to claim 19, wherein
the at least one connection region includes a plurality of connection regions that are in contact with the plurality of JFET regions, respectively, and that connect each of the plurality of BPW regions and each of the plurality of body regions, and
the plurality of connection regions includes a connection region that is provided on each of the plurality of first pillar regions.

24. The silicon carbide semiconductor device according to claim 19, wherein
the at least one connection region includes a plurality of connection regions that are in contact with the plurality of JFET regions, respectively, and that connect each of the plurality of BPW regions and each of the plurality of body regions, and
each of the plurality of connection regions are provided in contact with an entire side surface on one side of each of the plurality of trenches.

25. The silicon carbide semiconductor device according to claim 19, wherein
the at least one connection region includes a plurality of connection regions that are in contact with the plurality of JFET regions, respectively, and that connect each of the plurality of BPW regions and each of the plurality of body regions, and
the plurality of connection regions are provided in contact with entire side surfaces on both sides of some of the plurality of trenches, and are provided only at intersections of the plurality of BPW regions and the plurality of second pillar regions below other some of the plurality of trenches.

26. The silicon carbide semiconductor device according to claim 1, wherein
each of the plurality of second pillar regions and each of the plurality of BPW region are directly connected to each other in 80% or more in number of the intersections of the plurality of second pillar regions and the plurality of BPW regions.

27. The silicon carbide semiconductor device according to claim 19, wherein
the at least one connection region includes a plurality of connection regions that are in contact with the plurality of JFET regions, respectively, and that connect each of the plurality of BPW regions and each of the plurality of body regions, and
each of the plurality of second pillar regions and each of the plurality of BPW regions are connected via each of the plurality of connection regions to each other in 80% or more in number of the intersections of the plurality of second pillar regions and the plurality of BPW regions.

28. A silicon carbide semiconductor device comprising:
an n-type silicon carbide substrate having a first main surface and a second main surface that are opposed to each other;
an SJ region formed of silicon carbide and provided on the first main surface of the silicon carbide substrate; and
an MOSFET region provided on an upper surface of the SJ region,
wherein the SJ region includes a plurality of n-type first pillar regions and a plurality of p-type second pillar regions that extend in a first direction parallel to the first main surface and that are alternately aligned in a second direction parallel to the first main surface and perpendicular to the first direction, and
the MOSFET region includes:
a plurality of body regions formed of p-type silicon carbide, extending in the second direction, and aligned in the first direction at a second repetition interval that is shorter than a first repetition interval that is a repetition interval of the plurality of second pillar regions.

29. The silicon carbide semiconductor device according to claim 28, wherein
the plurality of body regions are connected to each of the plurality of second pillar regions.

30. The silicon carbide semiconductor device according to claim 28, wherein
the MOSFET region includes a plurality of JFET regions formed of n-type silicon carbide and provided between the plurality of body regions.

31. The silicon carbide semiconductor device according to claim 28, wherein
the MOSFET region includes:
a plurality of impurity regions formed of n-type silicon carbide and provided in surface layers of the plurality of body regions, respectively;
a plurality of body contact regions formed of p-type silicon carbide, having lower resistivity than the plurality of body regions, and extending from the surface layers of the plurality of impurity regions through the plurality of impurity regions to the plurality of body regions, respectively; and
a plurality of gate electrodes provided via a gate insulating film on each of the plurality of body regions between each of the plurality of impurity regions and each of the plurality of JFET regions,
the silicon carbide semiconductor device further comprising:
a top electrode provided on the plurality of body contact regions; and
a bottom electrode provided on the second main surface of the silicon carbide substrate.

32. The silicon carbide semiconductor device according to claim 28, wherein
each of the plurality of second pillar regions and each of the plurality of body regions are directly connected to each other.

33. The silicon carbide semiconductor device according to claim 31, wherein
each of the plurality of body contact regions penetrates each of the plurality of body regions to come in contact with each of the plurality of second pillar regions, and
each of the plurality of second pillar regions and each of the plurality of body regions are connected via each of the plurality of body contact regions to each other.

34. The silicon carbide semiconductor device according to claim 1, wherein
each of the plurality of second pillar regions and each of the plurality of body regions are directly connected to each other in 80% or more in number of intersections of the plurality of second pillar regions and the plurality of body regions.

35. The silicon carbide semiconductor device according to claim 1, wherein
each of the plurality of second pillar regions and each of the plurality of body regions are connected via each of the plurality of body contact regions to each other in 80% or more in number of intersections of the plurality of second pillar regions and the plurality of body regions.

36. An electric power converter comprising;
a main conversion circuit that includes the silicon carbide semiconductor device according to claim 1 and that converts and outputs input electric power;
a driving circuit that outputs a drive signal for driving the silicon carbide semiconductor device to the silicon carbide semiconductor device; and
a control circuit that outputs a control signal for controlling the driving circuit to the driving circuit.
